(19) United States
(12) Patent Application Publication
(10) Pub. No.: US 2025/0202433 A1
(43) Pub. Date: Jun. 19, 2025

(54) COMBINING NETWORK, AND APPLICATIONS INCLUDING DOHERTY AMPLIFIERS

(71) Applicant: Peter V. Wright, Cascais (PT)

(72) Inventor: Peter V. Wright, Cascais (PT)

(21) Appl. No.: 18/538,782

(22) Filed: Dec. 13, 2023

(51) Int. Cl. H03F 1/02; H03F 1/56; H03F 3/45

(52) U.S. Cl. CPC H03F 1/0288; H03F 1/56; H03F 3/45; H03F 2200/451

(57) ABSTRACT

A dual-T network configured as a three-port combiner provides signal paths from two input ports to an output port, with near 0° insertion phase along one path, near ±90° insertion path along the other path, and impedance step-up along both paths. Disclosed combiners provide superior loss and impedance matching characteristics over wide (15%) bandwidth, and are suitable for use in Doherty amplifiers, which can provide high efficiency over about 10 dB output power levels, the power levels being adjusted dynamically or under switched control. Single-ended and differential Doherty amplifiers are disclosed. The combiners and Doherty amplifiers are suitable for mobile phones and other modern RF products, including battery powered products. The combiners can also serve as general-purpose quadrature couplers. Variations and performance graphs are presented.

### BACKGROUND

Battery powered RF transmitters are ubiquitous. Efficiency of an RF transmitter has a direct impact on battery lifetime, product size and weight, and product heating. In many applications, it can be desirable to operate the RF transmitter at variable transmit power levels or over a wide range of operating frequencies. Some existing techniques can provide optimized efficiency at one output power level, but can suffer significant drop-off in efficiency at other power levels. Some existing techniques can be effective over a narrow frequency band, but can suffer increasing losses over a wider bandwidth. Some existing techniques can require bulky waveguide components which are unsuitable for compact modern products.

Accordingly, there remains a need for improved techniques to couple amplifiers to loads, including across a wide operating frequency range or over a wide range of output power.

### SUMMARY

In brief, examples of the disclosed technologies provide innovative coupler architectures offering notable improvements over conventional designs. Interacting T-networks can provide direct step-up of impedance, and low insertion phase in one signal path. Innovative couplers can provide wide operating bandwidth, low loss, and can be fabricated compactly using discrete reactive components. These couplers can be suitable for many modern products.

In some applications, innovative couplers can combine power from two amplifiers, such as the main amplifier and peaking amplifier of a Doherty amplifier configuration. Such amplifiers can provide high efficiency over a wider range of output power than a single amplifier, which can improve overall efficiency significantly under conditions of dynamically varying output power. Such amplifiers can also provide improved efficiency across multiple operating modes having different output power levels. Improved efficiency can lead to improved battery lifetime and/or smaller, lighter, and lower cost products. Amplifier configurations incorporating innovative couplers can inherit the wide bandwidth and low loss characteristics of these couplers.

In further applications, one or both of the main or peaking amplifier can be a differential amplifier, which can reduce distortion and further increase efficiency, in combination with all the advantages noted above for a basic Doherty amplifier configuration, e.g. using single-ended main or peaking amplifiers. In some examples, a differential pair of main or peaking amplifier outputs can be combined using a first stage reactive coupler, the output of which can be coupled to a corresponding input port of a second stage dual-T combining network. Advantageously, a shunted inductor lattice coupler (SILC) can be used as the first stage coupler, providing low loss and wide operating bandwidth as compared to some other couplers.

The foregoing and other objects, features, and advantages of the invention will become more apparent from the following detailed description, which proceeds with reference to the accompanying figures.

### BRIEF DESCRIPTION OF THE DRAWINGS

FIG. 1 is a chart depicting an illustrative modulated waveform which can be used in some examples of the disclosed technologies.

FIG. 2 is a chart depicting examples of power amplifier efficiency and probability distributions of modulated waveforms which can be used with some examples of the disclosed technologies.

FIG. 3 is a simplified schematic diagram of an example parallel amplifier which can be implemented using the disclosed technologies.

FIG. 4 is a simplified schematic diagram of a classic Doherty amplifier.

FIG. 5 is a simplified schematic diagram of a Doherty amplifier which can be implemented using the disclosed technologies.

FIG. 6 is a circuit diagram of a first example discrete combining network for a Doherty amplifier, using series Pi networks.

FIG. 7 is a circuit diagram of a second example discrete combining network, using series T-networks.

FIG. 8 is a circuit diagram of a third example discrete combining network, using series T-networks.

FIG. 9 is a circuit diagram of a first example dual-T combining network according to the disclosed technologies.

FIG. 10 is a circuit diagram of a second example dual-T combining network according to the disclosed technologies.

FIG. 11 is a chart showing insertion gain vs. insertion phase for a low-pass Tee network.

FIG. 12 is a chart showing insertion gain vs. insertion phase for a high-pass Tee network.

FIG. 13 is a model of a dual-T combining network with phantom shunt reactances, illustrating a principle of operation of examples of the disclosed technologies.

FIG. 14 is a simplified schematic diagram of a differential amplifier coupled to an output combining network, which can be incorporated into examples of the disclosed technologies.

FIG. 15 is a circuit diagram of a differential Doherty amplifier coupled to an example output combining network according to the disclosed technologies.

FIG. 16 is a chart depicting example design curves for variable balance between main and peaking Doherty amplifiers coupled according to the disclosed technologies.

FIG. 17 is a chart depicting examples of efficiencies of a single power amplifier and Doherty amplifiers coupled according to the disclosed technologies.

FIG. 18 is a flowchart of an example method according to the disclosed technologies.

FIG. 19 is a chart series depicting input impedance vs. backoff power for several Doherty amplifier configurations.

FIG. 20 is a chart series depicting insertion gain across an operating frequency range for several combining networks.

FIG. 21 is a chart series depicting input and output impedances across an operating frequency range for several combining networks.

FIG. 22 is a chart series depicting input impedance, output impedance, and gain across an operating frequency range for several differential combining networks.

### DETAILED DESCRIPTION

### Introduction

Battery powered RF transmitters are found in personal electronics (phones; laptop and tablet computers; wireless peripherals such as mice, keyboards, and headsets; smart watches; smart speakers; and music players), home electronics (alarm system sensors; remote controllers for televisions, media players, stereo amplifiers, and other appliances), automotive electronics (key fobs, remote starters), as well as other products (drones, cameras, bike computers, irrigation controllers). Some devices have multiple RF transmitters.

Practical applications often call for an RF transmitter to operate with output power levels variations on the order of 10 dB or greater, and over bandwidths greater than 10% of a center frequency.

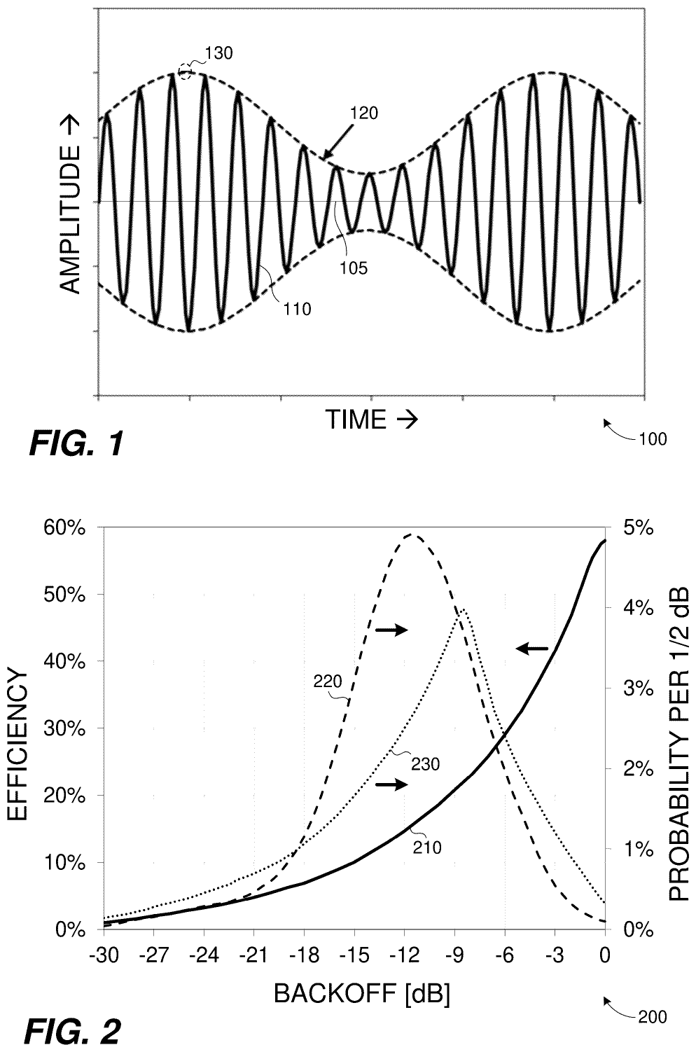

FIG. 1 is a chart 100 depicting an illustrative modulated waveform. The waveform amplitude (e.g. voltage or current feeding a transmit antenna, or electric field of a radiated signal) is shown on the vertical axis, with line 105 representing zero amplitude. Time is shown on the horizontal axis. Solid line 110 shows the waveform amplitude. As illustrated, waveform 110 is amplitude modulated and has a time varying envelope shown by dashed line 120. Envelope 120 has a peak 130 at which the transmitted power is maximum (peak envelope power, or “PEP”). The illustrated waveform shows that the transmitted power is often significantly less than PEP, a feature shared by many modulation schemes. Additionally, all modulation schemes cause frequency spreading of the transmitted signal.

Output power can also vary for other reasons. Some communication standards support throttling transmit power based on signal-to-noise ratio (SNR) at a receiving station, so that a transmitter can transmit at a low power level to a nearby receiver and at a higher power level to a farther receiver.

Factors other than modulation can also contribute to operating frequency range of an RF transmitter. For example, some communication standards assign frequency channels to RF transmitters within a supported RF band. A given RF transmitter can be specified to operate on whichever channel it is assigned.

FIG. 2 is a chart 200 depicting power amplifier efficiency and probability distributions of modulated waveforms as a function of output power. Efficiency and probability density are shown on the two vertical axes, and power backoff is shown on the horizontal axis-a backoff of 0 dB being the maximum output power of the amplifier.

Graph 210 (solid line) shows representative efficiency of a power amplifier module (power amplifier efficiency, PAE). The efficiency is seen to drop monotonically from nearly 60% at maximum power (0 dB backoff) to 30% at −6 dB backoff, and to even lower values with further backoff. At low output power, a surplus of DC power can be available at the amplifier, providing the amplifier with headroom to respond to rapid changes in output power level. But, at lower output power levels, the surplus DC power can be ohmically dissipated, leading to low efficiencies.

Graphs 220 (dashed line), 230 (dotted line) show probability density for representative quadrature amplitude modulation (QAM) and wideband code division multiple access (WCDMA) waveforms respectively. Graphs 220, 230 demonstrate that an amplifier with nominal 60% efficiency (at maximum output power) spends most of its time operating between about 15-30% efficiency for WCDMA, and between about 10-25% efficiency for QAM.

However, the innovative couplers are not limited to Doherty amplifier applications. Particularly, innovative couplers disclosed herein have unique characteristics that differentiate them from prior-art quadrature couplers, namely ˜0° phase shift in one path, and an output impedance at a combining node that exceeds input impedance at each input port. Innovative couplers may have approximately +90° phase shift in the other path. These properties render innovative couplers of particular interest to Doherty power amplifiers which can efficiently support continuously varying dynamic output power. Innovative couplers are also advantageous in RF transmitters having selectable output power. Still further, innovative couplers can be used as combiners or splitters anywhere a quadrature combiner or quadrature splitter is applicable.

Incorporated into various Doherty amplifier configurations as described herein, innovative combiners enable significant improvements to efficiency under conditions of varying output power level. Disclosed innovations are suitable for implementation in a wider range of compact wideband modern products.

### Terminology

To facilitate review of the various embodiments, the following explanations of terms are provided. Occasionally, and where clear from the context, a term may also be used in a different meaning.

An “amplifier” is a device or circuit for increasing the amplitude or power of an oscillatory signal. Amplitude or power can be quantified in Volts, Amperes, Watts, dB, dBm, or any similar units. An amplifier is commonly fabricated using one or more transistors in various configurations. Nonlimiting examples of transistor amplifier configurations include common emitter, common base, or push-pull. Amplifiers can be grouped, for example in parallel branches or in series stages. To illustrate, a preamplifier can be followed by another amplifier stage. A “power amplifier” is an amplifier not followed by another amplifier stage. While some power amplifiers can be preceded by another amplifier stage, this is not a requirement and a single amplifier can be a power amplifier. In examples, a power amplifier can be coupled to an antenna or to another load. A “differential power amplifier” (or simply “differential amplifier”) is a parallel combination of two amplifiers configured to accept differential input signals and generate differential output signals. Thus, a combination of the output signals is an amplified version of the combined input signals.

“Bandwidth” refers to the width of a frequency range, which can variously be (i) the range of frequencies occupied by a signal, (ii) a targeted operating frequency range of a circuit or component, or (iii) the frequency range over which a performance parameter meets a criterion. In some usage, bandwidth can be defined by a fall-off in power density or performance below a peak value. To illustrate, a 3 dB bandwidth of an amplifier can be the maximum width of a frequency range for which the amplifier gain is within 3 dB of the peak value of gain. A 3 dB bandwidth of a signal can be the maximum width of a frequency range for which spectral power density is within 3 dB of the peak spectral power density.

A “capacitor” is a two-terminal circuit component that, with voltage applied across the terminals, stores charge on the terminals, stores electric field energy between the terminals, and has a Q value of at least 10. A capacitor can be characterized by its “capacitance” which is the ratio of charge on either terminal to voltage across the terminals. Capacitors are commonly used as reactive elements in circuits, and can provide a frequency-dependent negative reactance. Some capacitors described herein can be implemented with specific capacitance values to impart, in combination with other circuit components, desirable properties to a circuit. Other capacitors can be implemented to provide low reactance values between the terminals, without providing a DC path. Such capacitors can be referred to as “bypass” or “DC blocking” capacitors, and can commonly be chosen with widely varying capacitance values without significantly compromising circuit performance. Common capacitors can have a quality factor (“Q”) up to about 100, and can be modeled as lossless devices or, for greater accuracy, with accompanying parasitic resistances or inductances. Capacitors can be implemented as discrete or distributed components, including as a composite of multiple connected reactive elements.

A “carrier” is a signal which can be modulated to carry information. “Carrier frequency” refers to the frequency of a carrier. The carrier need not be present in the modulated signal, as illustrated by suppressed carrier signaling techniques.

A “communication terminal” is an apparatus capable of receiving or transmitting information-bearing electromagnetic signals over a medium (which can include vacuum). A “mobile phone” is a portable communication terminal, commonly powered by a battery. A “cell phone” is a mobile phone configured to operate over a cellular telephone network. Non-limiting examples of communication terminals include cell phones; base stations; access points; television sets; set top boxes; radios; network interface cards; cable or fiber head ends; satellites and associated ground terminals; or other transmitters or receivers for wireless, wired, or optical communication networks.

A “coupler” is a circuit device having N+1 ports for an integer N≥2, which can also be dubbed an “N-to-1 coupler”. A coupler couples a signal at one port to N signals at the other N ports. In some instances, the signal at the one port is an input, and the other N signals are outputs. Such a configuration is dubbed a “splitter”. In other instances, the signal at the one port is an output, and the other N signals are inputs. Such a configuration is dubbed a “combiner”. A given coupler can be variously operated as a splitter or a combiner according to the environment in which it is used and what signal(s) are applied to its port(s). Although less common, a given coupler can function as both a splitter and a combiner at same or different times, or at same or different frequencies. Some couplers disclosed herein are three-port devices (N=2), but this is not a requirement. Other examples are disclosed having cascaded three-port couplers forming five-port (four-to-one) couplers. A coupler, combiner, or splitter comprising multiple components can be termed a “coupling network,” “combining network,” or “splitting network,” respectively.

“DC” refers to any electrical signal that performs its function without requiring an oscillatory component. For example, a bias power supply can provide a DC bias voltage to a circuit. The label DC does not preclude temporal variation. To illustrate, a DC signal can be switched on or off, can droop over time, or can exhibit imperfect load regulation or line regulation. In some examples, the DC signal amplitude may be varied at a rate close to the frequency of amplitude modulation of the carrier. This so-called “envelope modulation frequency” can be much lower than the carrier frequency, often less than 10% or less than 1% of the carrier frequency. Additionally, due to non-ideal characteristics of circuit components, DC signals can be superposed with oscillatory leakage or ripple. The term DC can also describe components associated with DC signals. To illustrate, a DC blocking capacitor can present a high impedance to a DC signal.

The term “direct” refers to a coupling of two electrical nodes or devices in such a way as to allow DC current to flow, commonly by a segment of a conductive material such as a wire. Directly coupled nodes or devices are said to be “tied” together.

The term “distribute” refers to dividing a received signal into multiple parts directed to respective paths of a circuit. Each of the parts carries a portion of the power in the received signal.

A “Doherty amplifier” is a particular type of amplifier configuration having two amplifiers operating in parallel, with outputs combined in a combining network. The concept is attributed to U.S. Pat. No. 2,210,028 by William Doherty. One amplifier, dubbed a “main amplifier” (also “carrier amplifier”) can provide output power across a full range of operating power levels. The main amplifier can often be operated in class A/B or class B modes. The other, dubbed a “peaking amplifier” can contribute significant output power at high output power levels and insignificant output power at low output power levels. For example, a peaking amplifier can contribute less than 10% of the total output power when the output power is below a first threshold, and can contribute more than 30% of the total output power when the output power is above a second threshold. In some examples, the contribution of the peaking amplifier can vary smoothly as output power level varies while, in other examples, the peaking amplifier can be switched on or off. The main amplifier can provide at least 30% of the total output power across the full range of output power levels, and at least 90% of the total output power when the output power level is below the first threshold. The Doherty amplifier can provide high efficiency over a wider range of output power than other amplifier configurations. However, as described herein, conventional combiners have been bulky or have suffered from poor performance over bandwidth and, till now, Doherty amplifiers have not been favored in modern battery-powered RF transmitters. The disclosed technologies provide superior performance and can make Doherty amplifiers very attractive for a wide range of modern products.

The “efficiency” of an amplifier circuit or module, with or without passive networks or power supply circuits to which it is coupled, is based on RF output power (Pout), RF input power (Pin), and DC power consumed (Pdc). Unless otherwise noted, efficiency herein refers to “power added efficiency” (PAE) defined as PAE=(Pout-Pin)/Pdc. A numerical value of efficiency can depend on the extent of the amplifier circuit under consideration. Because passive networks and power supply circuits can dissipate power, even if power dissipation is small, efficiency often decreases as these are combined with an underlying “raw amplifier.” A raw amplifier is an amplifier circuit all ports of which are transistor terminals. Passive networks can include impedance transformers, splitters, combiners, or power distribution networks. Power supply circuits can include DC-DC converters, linear regulators, Zener diodes, RF chokes, or resistors.

“Ground” refers to one or more nodes or conductive portions of a circuit at a constant electrical potential. “Circuit ground” refers to a ground that is at a DC reference voltage for the circuit (dubbed “ground voltage” and sometimes assigned a DC voltage of 0 V). “Virtual ground” refers to a ground that can be at a fixed or variable DC voltage other than the ground voltage, but which cannot support oscillatory (e.g. RF) signals close to the carrier frequency. For oscillatory signals within the operating bandwidth of the circuit, the impedance between a virtual ground and circuit ground can be less than 20% of the characteristic impedance of signal circuits coupled to the virtual ground. A “grounding node” refers to a node of a circuit device configured to be a circuit ground (e.g. tied to the ground voltage) or a virtual ground (e.g. coupled to circuit ground through a bypass capacitor).

“Impedance” (commonly denoted “Z”) is a property of a circuit or component that is a ratio of voltage to current. “Input impedance” is the ratio of (i) voltage applied to the circuit or component to (ii) current that flows in the circuit or component. “Output impedance” is the differential decrease in output voltage for an incremental increase in output current from the circuit or component. Impedance can be complex: its real and imaginary parts are dubbed “resistance” (R) and “reactance” (X) respectively. The reciprocal of impedance is dubbed “admittance” (Y), which has real and imaginary parts dubbed “conductance” (G) and “susceptance” (B) respectively. A “characteristic impedance” of a circuit or component is an impedance value which, if coupled to a port of the circuit or component, minimizes reflections at that port. A circuit or component can have different characteristic impedances on different ports. A circuit or component can have different characteristic impedances at a given port at different frequencies or under different operating conditions. Given a first circuit or component having an output impedance and outputting a signal to a second circuit or component having an input impedance, the output and input impedances are said to be “matched” if they are equal to within a tolerance. In the art, the tolerance for matching impedances can be specified in terms of a magnitude of the reflection coefficient at the interface between the two circuits or components. For example, a 5% reflection coefficient corresponds to about 10% mismatch between impedance values, 90% power transmission, and 10% power reflection. Similarly {1, 2, 10, 20} % reflection coefficients correspond to about {2, 4, 20, 42} % mismatch between impedance values, {98, 96, 81, 64} % power transmission, and {2, 4, 19, 36} % power reflection respectively.

An “inductor” is a two-terminal circuit component that, with current applied through the component, encircles magnetic flux, stores magnetic energy in a volume enclosed by or proximate to the component, and has a Q value of at least 10. An inductor can be characterized by its “inductance” which is the ratio of encircled magnetic flux to current passing through the terminals. Inductors are commonly used as reactive elements in circuits, and can provide a frequency-dependent positive reactance. Some inductors described herein can be implemented with specific inductance values to impart, in combination with other circuit components, desirable properties to a circuit. Other inductors can be implemented to provide high reactance values between the terminals, while also providing a low resistance DC path. Such inductors can be referred to as “RF blocking” or “choke” inductors, and can commonly be chosen with widely varying inductance values without significantly compromising circuit performance. Common inductors can have a quality factor (“Q”) up to about 60, and can be modeled as lossless devices or, for greater accuracy, with accompanying parasitic resistances or capacitances. Inductors can be implemented as discrete or distributed components, including as a composite of multiple connected reactive elements.

“Insertion phase” is the phase shift of a signal from a first port where an input signal enters a circuit to a second port where a corresponding output signal exits from the circuit. With negative insertion phase, the exiting signal “lags” the input signal. With positive insertion phase, the exiting signal “leads” the input signal.

A “load” is a circuit or component coupled to receive a signal from another circuit or component dubbed a “source”. Common loads include an antenna, a resistive termination, or an amplifier stage. An “antenna” is a device that couples electromagnetic radiation in a medium to or from electrical or electromagnetic signals in a circuit. Common sources include an amplifier, a modulator, or an oscillator.

A “node” or “terminal” is an attachment point of an electrical component. In some instances, a node can be a junction between two or more components in an electrical circuit. The components can be discrete components (such as some inductors or capacitors), distributed components (such as waveguide components), or simply sections of conductive wiring, in any combination. A node of an electrical device (such as a coupler) can be coupled to an external component such as wiring, a ground plane, or another electrical component.

An “operating frequency” is a signal frequency at which a circuit or component operates or is intended to operate. An operating frequency can be a single frequency or can span a range of frequencies dubbed an “operating frequency range.” Signal frequencies can be distributed among this range due to modulation (including direct sequence spread spectrum), due to channel selection (including frequency hopping), or both. Commercial products are often specified to operate with published performance parameters over a published frequency range. A “target operating frequency range” is the frequency range over which a circuit or component is specified to operate. Particularly, properties specified within a targeted operating frequency range may not be met at another frequency outside this range.

Two periodic signals at a common frequency are “out-of-phase” if a phase difference between them is in a range [120°, 240°]. Two out-of-phase signals are “opposite phase” if the phase difference between them is in a range [170°, 190°]. Two oppositely phased signals are “differential” if they exhibit the same modulation or carry the same information. Two out-of-phase signals are “balanced” if they have power levels within 1 dB of each other, and “unbalanced” otherwise. Statements herein referring to any one of these classes are understood to be equally applicable to any subset of that class. To illustrate, a statement about out-of-phase signals implies the same for differential signals or unbalanced signals.

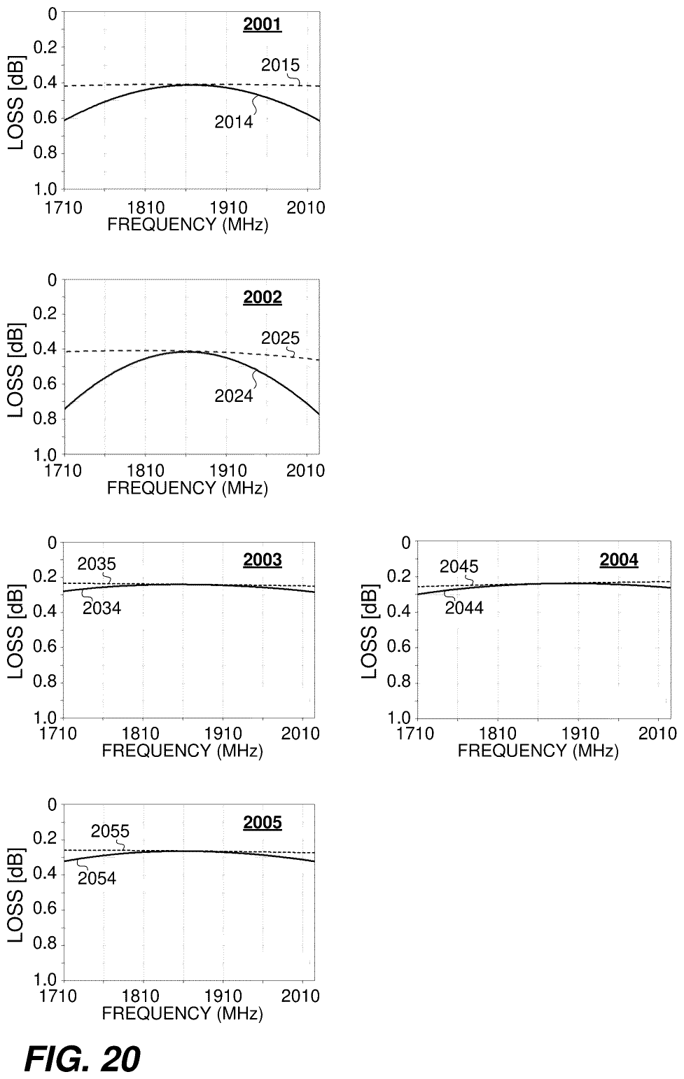

“Performance characteristics” of a circuit device are quantifiable parameters that indicate a relationship between output and/or input signals of the device. Performance characteristics may be dependent on a circuit environment in which the circuit device is placed. To illustrate, output signal characteristics of a device can vary according to whether the device is coupled to a matched load or a mismatched load; or can vary according to the bias voltage applied to the device. Non-limiting examples of performance characteristics relevant to disclosed examples include: “efficiency,” described above; “gain” which can refer to a ratio of output power to input power; “input impedance” which can refer to the ratio of voltage applied at a port to the current flowing into that port, and which can apply to both input ports or output ports of a device; “insertion gain” which can be a ratio of output power to input power, and which can apply to coupler or splitter configurations of disclosed couplers; “insertion loss” which can be a ratio of input power to output power, e.g. the reciprocal of insertion gain, and is further described in context of FIG. 20; or “insertion phase,” described above. “Bandwidth” can be a design requirement of a frequency range over which a circuit device is required to operate, optionally with a particular value (or, range of values) of a performance characteristic.

“Phase” is a property of an oscillatory signal at a given frequency, which indicates a temporal offset (commonly measured in units of angle) relative to a reference at the given frequency. Inasmuch as relative phases and changes in phase are often of interest, the reference can be virtual, e.g. no reference signal need be present. Two periodic signals at a common frequency are “in-phase” if a phase difference between them is in a range [−60°, 60°]. Two periodic signals at a common frequency are “in quadrature” if a phase difference between them is in a range [60°, 120°] or [−120°, −60°]. Out-of-phase signals are described separately herein.

A “Pi network” is a two-port network comprising a chain of three components connected in series. The ends of the chain are coupled to grounding nodes and the intermediate nodes are the two ports of the Pi network.

A “port” is an attachment point of an electrical device at which a time-varying signal can be inputted or outputted. Thus, ports can exclude ground connections. For example, a four-port device can be transformed into a three-port device by tying one of the four ports to circuit ground. The presence of a time-varying signal does not preclude a port from also receiving or delivering a DC signal.

“Power” is the energy carried per unit time by a signal. Power can be measured in W, dBm, or similar units. “Output power” is the power delivered from a circuit, such as an amplifier or combining network, to another circuit or a load. Some examples of the disclosed technologies operate over a range of output power levels. “Rated power” is the maximum output power which a circuit is designed to deliver. “Backoff” is the ratio output power to the rated power, often specified in dB. To illustrate, if rated power is 10 mW (+10 dBm), −10 dB backoff corresponds to output power of 1 mW (0 dBm).

The “Q” or quality factor of an electrical component having impedance Z=R+jX is Q=|X/R|. In some examples, capacitors and inductors can have Q≥100 and Q≥50 respectively over a target operating frequency range, but this is not a requirement and other examples can use capacitors and inductors have Q of at least 10. Q values can be as high as 10,000 and are often limited by parasitic effects such as resistance of conductive materials, leakage of dielectric materials, or stray fields. The Q of a T-network is the minimum Q value of its three arms. The Q of two or more coupled T-networks is the minimum Q value of each constituent T-network. Components or networks having Q≥30 are termed “lossless” herein. Innovative couplers described herein can be implemented with lossless reactive elements, but this is not a requirement.

A “reactor” (or “reactive element”) is an electrical component having impedance Z=R+jX, with |X|>|R| (e.g. Q>1) over a target operating frequency range. Inductors and capacitors can be reactors. Common reactors described herein have Q values of at least 10.

“RF” stands for radio frequency, covering a range from about 300 kHz to about 300 GHz (the RF frequency range), and can refer to electromagnetic signals or processes in that frequency range, or to circuit devices operating in that frequency range.

The term “signal” refers to any propagating electromagnetic energy in the form of current, voltage, electric field, or magnetic field, in any combination. Signals can flow along wires, along waveguides, through electrically conductive, dielectric, or electrically insulating media, or through a vacuum. Some signals of interest herein can carry information or can exhibit oscillatory behavior, however neither of these are requirements. Signals can be acted on by a wide range of devices, including amplifiers and couplers (including both combiner and splitter configurations). Commonly, such devices receive signals dubbed “input signals” (or simply “inputs”) and generate signals dubbed “output signals” (or simply “outputs”). A signal can have a magnitude, which can be denominated in Volts, Amperes, Watts, dB, dBm, or any similar units. An oscillatory signal at a given frequency can also have a “phase”, which indicates a temporal offset (commonly measured in units of angle) relative to a reference at the given frequency. Inasmuch as relative phases and changes in phase are often of interest, the reference can be virtual, e.g. no reference signal need be present.

Some coupling networks disclosed herein can include or can work with one or more of a three-port shunted inductor lattice coupler (“SILC”). SILC's are further described in U.S. Pat. No. 11,742,819 by a common inventor and incorporated herein by reference in entirety. An example SILC has first, second, and third ports and includes: a first inductor coupled between the first port and a first grounding node; a second inductor coupled between the second port and a second grounding node, wherein the first inductor and the second inductor have a predetermined mutual magnetic coupling factor; a third inductor coupled between the first port and the third port; a first capacitor coupled between the first port and a third grounding node; and a second capacitor coupled between the second port and the third port. Each grounding node can be a circuit ground or a virtual ground coupled to circuit ground by one or more bypass capacitors. In varying examples, the mutual magnetic coupling factor can be between 0.6 and 1.0, between 0.1 and 0.6, or between 0.0 and 0.1.

A “substrate” is a generally planar medium upon which circuit elements can be formed (e.g. by photolithographic, chemical etch, or deposition processes) or mounted (e.g. by soldering). Non-limiting examples of substrate materials include FR-4, DUROID®, silicon, silicon dioxide, silicon carbide, or alumina. In examples, alternating electrically conductive and electrically insulators “layers” can be formed on a substrate, with electrical devices defined by patterns in the conductive layers and, optionally, doping or etch in the insulating layers, with conductive paths (“vias”) formed between conductive layers as needed. Components of combining networks, amplifiers, or other circuitry disclosed herein can be formed on or mounted on one or more substrates.

A “T-network” is a two port network having a wye (Y shaped) topology, with a common node coupled to the two ports and a grounding node through respective arms of the wye. Some combining networks described herein incorporate two coupled T-networks, dubbed a “dual-T combining network” or simply “dual-T network.” “Tolerance”

“Tolerance” refers to a variation of an electrical parameter or performance characteristic about an ideal or design value of that parameter or characteristic. Tolerances can be specified in absolute or relative units. Where no tolerance is specified, two like signals or associated measures can be considered equal if they are within about 25% or 1 dB in power, or 12% in a linear scale (e.g. volts). Other parameters (e.g. impedances, DC voltages, or currents) can be considered equal if their values are within about 12%.

### Example Parallel Amplifier

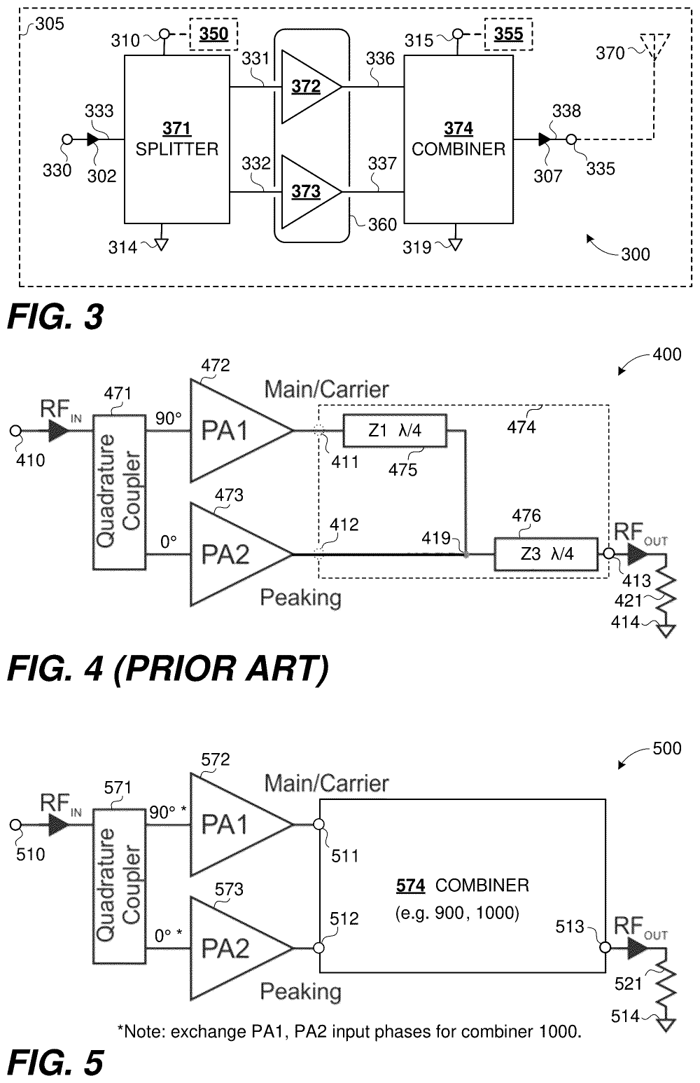

FIG. 3 is a simplified schematic diagram of an example parallel amplifier system 300 which can be implemented using the disclosed technologies.

Amplifier system 300 can include a pair of couplers 371, 374 and a pair of amplifiers 372, 373. One or both of couplers 371, 374 can be implemented as an innovative dual-T coupler as described herein or as a SILC. Arrows 302, 307 indicate a direction of signal power flow through system 300. In some examples, dual amplifier 360 or amplifier system 300 can be a power amplifier.

Optional components that can be included in some embodiments of system 300 are shown in dashed outline. For example, port 335 can be coupled to antenna 370. System 300 can be integrated into product 305, such as a cell phone, another communication terminal, or another product as disclosed herein.

In some examples, amplifiers 372, 373 can be configured to operate as a Doherty amplifier, receiving signal inputs 331, 332 in quadrature from coupler 371 and transmitting signal outputs 336, 337 in quadrature to coupler 374.

In other examples, amplifiers 372, 373 can be configured to operate as differential amplifier 360, receiving out-of-phase signal inputs 331, 332 from coupler 371 and transmitting out-of-phase signal outputs 336, 337 to coupler 374.

Amplifier system 300 can have an input port 330 and an output port 335. Input signal 333 received at port 330 can be provided to a coupler 371 configured as a differential or quadrature splitter to produce out-of-phase or in-quadrature signals 331, 332 which can be outputted from splitter 371 and inputted to dual amplifier 360. In examples, splitter 371 can be an innovative coupler as disclosed herein, or a SILC. With reference to disclosed couplers, input signal 333 can be received at port P3 of an innovative coupler, and quadrature outputs can be provided from ports P1, P2. A similar configuration can be used for a SILC coupler 371. Optionally, terminal 310 of coupler 371 can be coupled to bias power supply 350, and terminal 314 can be tied to circuit ground. Bias power supply 350 can provide DC power to dual amplifier 360.

Output signals 336, 337 from amplifier 360 can be inputted to coupler 374 configured as a differential or quadrature combiner to produce combined signal 338. In examples, combiner 374 can be an innovative coupler as disclosed herein or a SILC. With reference to disclosed couplers, signals 336, 337 can be received at ports P1, P2 of an innovative coupler, and combined output 338 can be provided from port P3. A similar configuration can be used for a SILC coupler 374. Optionally, terminal 315 of coupler 374 can be coupled to a bias power supply 355, and terminal 319 can be tied to circuit ground. Bias power supply 355 can provide DC power to dual amplifier 360.

In some examples, terminals 310, 315 can be used to provide bias power to input and output stages of amplifier 360 while, in other examples, just one of terminals 310, 315 is sufficient to power amplifier 360. In further examples, terminals 310, 315 can be used to provide split voltage rails for amplifier 360, which can have same or opposite polarity.

In some examples, the configuration of system 300 can be implemented recursively. That is, one or both of amplifiers 372, 373 can itself be a parallel amplifier also according to FIG. 3. To illustrate, couplers 371, 374 can be a quadrature splitter and a quadrature combiner, implemented e.g. as innovative dual-T networks, and each amplifier 372, 373 can be implemented as a differential amplifier (with respective differential splitter similar to 371 and differential combiner similar to 374). The composite amplifier can operate as a differential Doherty amplifier as described further herein, e.g. in context of FIG. 15.

As another illustration of a recursive configuration, top-level couplers 371, 374 can be a differential splitter and a differential combiner, implemented e.g. as SILCs, and each amplifier 372, 373 can be implemented as a lower-level instance of FIG. 3 configured as a Doherty amplifier. Each (lower-level) Doherty amplifier can have a respective quadrature splitter and quadrature combiner, one or both of which can be an innovative dual-T coupler as described herein. This composite amplifier can also operate as a differential Doherty amplifier.

As a further illustration, recursive application of FIG. 3 can also be used to obtain required output power from smaller amplifier modules, without invoking Doherty operation, using innovative couplers, SILCs, or other couplers in various combinations.

### Example Classic Doherty Amplifier

FIG. 4 is a simplified schematic diagram of a classic Doherty amplifier 400, similar to that described by William Doherty in U.S. Pat. No. 2,210,028. Amplifier 400 can be seen as an instance of amplifier system 300, with input and output ports 410, 413 corresponding to ports 330, 335 of FIG. 3. Splitter 371, amplifiers 372, 373, and combiner 374 are implemented in FIG. 4 as quadrature coupler 471, amplifiers 472, 473, and combining network 474 respectively. Although not part of illustrated amplifier 400, load 421 is shown for clarity of illustration.

An input RF signal is received at port 410 and split into quadrature components having respective phases 90° and 0° as shown. The 90° signal passes through main amplifier 472 and the upper branch of combiner 474 to reach summing node 419. Main amplifier 472 can operate as a class A/B or class B amplifier, generating output RF power for all power levels. The 0° signal passes through peaking amplifier 473 and the lower-left branch of combiner 474 to reach summing node 419. Peaking amplifier 473 can operate as a class C amplifier, generating output power at high power levels and little or no power at low power levels, where it has a high output impedance.

In classic Doherty amplifier 400, combiner 474 is realized using waveguide sections 475, 476. Section 475 is matched to the output impedance Z1 of amplifier 472, and provides a 90° phase delay (−90° insertion phase) to the main signal, thus aligning the phases of main and peak signals at summing node 476. The combined output impedance of the amplifiers at summing node 419 is the parallel combination of Z1, Z2, where Z2 is the output impedance of amplifier 473. In a common configuration with Z1=Z2, the output impedance at node 419 is Z1/Z2. Illustratively, for Z1=Z2=8Ω, this combined output impedance is 4 (2. Amplifier load 421 is generally much higher than this, typically several tens of ohms and sometimes 50Ω. To match impedances, quarter wave section 476 can be implemented as an impedance transformer: a 50Ω load will appear as Z3²/(50Ω) at node 419. Thus, Z3=sqrt (4 Ω×50Ω)=14.1 Ω will match amplifiers 472, 473 to load 421 in this illustration. Z3 can be calculated similarly for other values of source and load impedances.

Nodes 411, 412 are input ports of combiner 474. Port 413 is an output port of combiner 474.

Classic Doherty amplifier 400 has not been popular in the modern era. For one reason, waveguide sections 475, 476 can be prohibitively bulky in cell phones and other compact modern devices. For another reason, combiner 474 works well at a spot frequency, but both impedance and phase matching deteriorate away from that spot frequency, leading to undesirable losses over common 10-16% bandwidths. Frequency dispersion of the network is exacerbated by the fact that the output of the combining network is reduced to approximately one-half of the value of the input impedances. Thus, the subsequent output impedance matching network is tasked with implementing twice the impedance transformation than would otherwise be required. The latter invariably reduces the effective bandwidth of the latter.

### Example Discrete Doherty Combiners

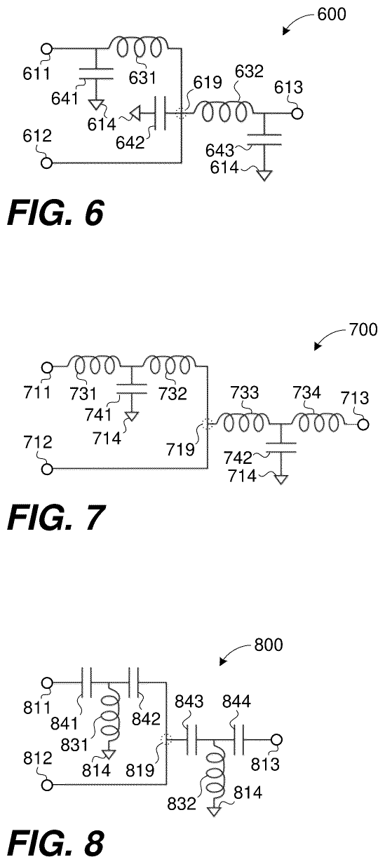

Variants of the waveguide combiner 474 can be built using discrete components. FIGS. 6-8 show some examples of combiners 600, 700, 800 which can be substituted for combiner 474 of FIG. 4.

FIG. 6 is a circuit diagram of a first example discrete combining network 600 using series Pi networks. Input ports 611, 612 correspond to combiner input nodes 411, 412 of FIG. 4, and output port 613 corresponds to output port 413. In network 600, quarter-wave section 475 of FIG. 4 is replaced by a low-pass Pi section formed by capacitor 641, inductor 631, and part of capacitor 642, and can be designed to have impedance Z1 matched to the output impedance of amplifier 472, while also providing-90° phase shift. Quarter-wave section 476 of FIG. 4 is replaced by a low-pass Pi section formed by part of capacitor 642, inductor 632, and capacitor 643, and can be designed to have impedance Z3 providing the required impedance match to a load (not shown) on output port 613. The direct low impedance connection from port 612 to intermediate node 619 mimics the direct connection from node 412 to summing node 419 in FIG. 4.

FIG. 7 is a circuit diagram of a second example discrete combining network 700 using series T-networks. Ports 711-713 are similar to corresponding ports 611-613 of FIG. 6. The underlying principle is the same as for FIG. 6, however sections 475, 476 are substituted by low-pass T-network sections instead of Pi network sections. Thus, the T-network formed by inductor 731, capacitor 741, and inductor 732 can provide −90° phase shift and impedance matched to amplifier 472; and the T-network formed by inductor 733, capacitor 742, and inductor 734 can provide impedance matching to a load (not shown) on output port 713.

FIG. 8 is a circuit diagram of a third example discrete combining network 800, also using series T-networks. Ports 811-813 are similar to corresponding ports 611-613 of FIG. 6. The underlying principle is the same as for FIGS. 6-7, however sections 475, 476 are substituted by high-pass T-network sections instead of low-pass sections. Thus, the T-network formed by capacitor 841, inductor 831, and capacitor 842 can provide +90° phase shift and an impedance matched to amplifier 472; and the T-network formed by capacitor 843, inductor 832, and capacitor 844 can provide impedance matching to a load (not shown) on output port 813. Because the phase shift in the first T-network is +90° instead of −90°, use of combiner 800 would involve configuring the input to amplifier 472 at −90° phase instead of +90° as shown in FIG. 4.

The combiners of FIGS. 6-8 are merely exemplary. Because waveguide sections 475, 476 can be substituted independently, each as a T-network or Pi-network, using either low-pass or high-pass topologies, there are four substitutions possible for each of sections 475, 476, and 16 possible implementations overall.

However, all 16 variants suffer from drawbacks inherited from the architecture of combiner 474: frequency response suffers at least because this architecture reduces impedance at a combining node before boosting impedance through an impedance transformation. Additionally, all variants employ at least two inductors, which can have lower Q values (hence more loss) than the waveguide sections they replace.

Accordingly, while discrete component combiners similar to 600, 700, 800 may be more compact than waveguide combiner 474, they too have not found favor in modern products.

### Example Innovative Doherty Amplifier

FIG. 5 is a simplified schematic diagram of a Doherty amplifier 500 which can be implemented using the disclosed technologies. Like amplifier 400, amplifier 500 can be seen as an instance of amplifier system 300, with input and output ports 510, 513 corresponding to ports 330, 335 of FIG. 3. Splitter 371, amplifiers 372, 373, and combiner 374 are implemented in FIG. 5 as quadrature coupler 571, amplifiers 572, 573, and combining network 574 respectively. Although not part of illustrated amplifier 500, load 521 is shown for clarity of illustration.

Components 571-573 can be similar to corresponding components described in context of FIGS. 3-4 or elsewhere herein, and are not described further. Unlike amplifier 400, amplifier can be realized with an innovative combiner 900, 1000 described below.

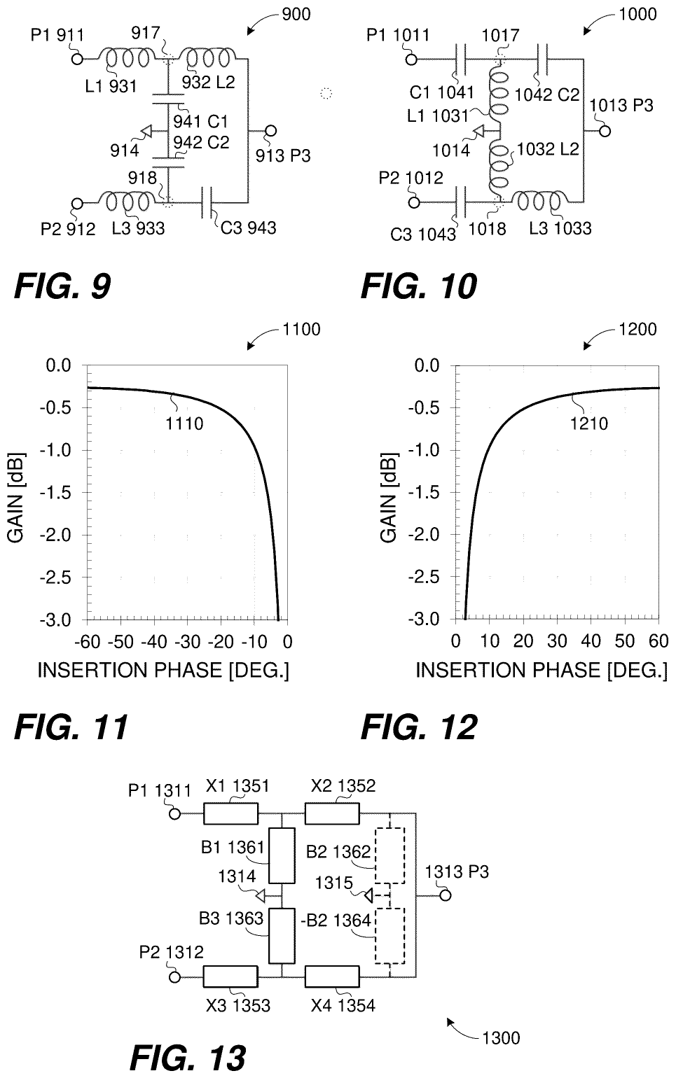

An input RF signal is received at port 510 and split into quadrature components having respective phases 90° and 0° as shown for combiner 900. The 90° signal passes through main amplifier 572 to input port 511 of combiner 574. Main amplifier 472 can operate as a class A/B or class B amplifier, generating output RF power for all power levels. The 0° signal passes through peaking amplifier 573 to input port 512 of combiner 574. Peaking amplifier 573 can operate as a class C amplifier, generating output power at high power levels and little or no power at low power levels, where it has a high output impedance. Port 513 is an output port of combiner 574, from which RF output power can be provided to load 521. As noted in FIG. 5, the amplifier input phases can be reversed (90°→0°, 0°→90°) when combiner 1000 is used. Operation of Doherty amplifier 500 with combiners 900, 1000 is described further herein, e.g. in context of FIGS. 9, 10.

As a Doherty amplifier, amplifier 500 can operate in a high power mode, where both main and peaking amplifiers contribute comparable power to load 521. In examples, the ratio of power provided by the main amplifier to the power delivered by the peaking amplifier can be in a range 1:2 to 2:1 or 1:3 to 3:1. In the high power mode, input impedances of combiner 574 can be matched to output impedances of the main and peaking amplifiers. The high power mode can correspond to a peak of efficiency.

Doherty amplifier 500 can also operate in a low power mode where the contribution of the peaking amplifier is insignificant. In examples, the main amplifier can provide at least 4× the power provided by the peaking amplifier in the low power mode. In the low power mode, the input impedance seen by the main amplifier can be 1.5-2.5 times the output impedance of the main amplifier. Amplifier 500 can have a second efficiency peak in the low power mode. The second efficiency peak can occur at an output power backoff between 2-12 dB.

Doherty amplifier 500 can also operate in a transition mode between the high and low power modes. The operating point of Doherty amplifier 500 can vary among these modes dynamically or under switched control.

Because of compact realization and superior performance of innovative couplers 900, 1000, as described herein, amplifier 500 can be advantageously incorporated in mobile phones, other communication terminals, or other products 305.

### Example Dual-T Combining Networks

FIGS. 9-10 show exemplary innovative combiners 900, 1000. Each comprises two T-networks, like combiners 700, 800. However, unlike combiners 700, 800, which have an input port 712, 812 at the junction of their respective T-networks, combiners 900, 1000 have their two T-networks joined at the combiner output port 913, 1013. Moreover, as described further herein, combiners 900, 1000 have one T-network with small phase shift, unlike combiners 700, 800 in which all T-networks are designed to replace a quarter wave section of waveguide, hence introducing −90° (or)+90° phase shift. Each combiner 900, 1000 can be used to realize combiner 574 of FIG. 5 or 374 of FIG. 3. Still further, combiners 700, 800 exhibit a step-down in impedance from input port 711, 811 to combining node 719, 819. In contrast, combiners 900, 1000 provide direct step-up of output impedance from input port P1 911, 1011 to combining node P3 913, 1013, enabling superior performance over bandwidth as described further herein.

FIG. 9 is a circuit diagram of innovative dual-T combining network 900. Ports 911-913 correspond to nodes 511-513 of FIG. 5. A first T-network, formed by inductor L1 931, capacitor C1 941, and inductor L2 932, can match output impedance Z1 of an amplifier coupled to port 911 and can provide about −90° phase shift (or in a range −80° to −100°) from port P1 911 to port P3 913. A second T-network formed by inductor L3 933, capacitor C2 942, and capacitor C3 943 can provide a small phase shift (e.g. between −10° and)+10° from port P2 912 to port P3 913. That is, phase shifts through inductor L3 933 and capacitor C3 943 can be arranged to cancel. Like the first T-network, the second T-network can also match the output impedance Z2 of an amplifier coupled to port 912. Still further, dual-T network 900 has enough degrees of freedom to provide a step up in impedance so that the output impedance Z3 at node P3 913 is matched to a load coupled thereto. Particularly, combiner 900 can be designed to provide |Z3|>max (|Z1|, |Z2|).

Introducing combiner 900 as combiner 574 in FIG. 5, a main signal introduced at port 911 (node 511) and a peaking signal introduced at port 912 (512) each reach output port 913 (513) in-phase, e.g. at 0° phase, adding together as desired. Notably, main amplifier 572 can be connected to the −90° arm of coupler 900 at port P1 911 and peaking amplifier 573 can be connected to the 0° arm of coupler 900 at port P2 912. This is because the output impedance of peaking amplifier 573 transitions from a matched impedance (e.g. on the order of 10 52) at full power to high impedance in a low output power state where amplifier 573 is cutoff. If peaking amplifier 573 was connected to the −90° arm of coupler 900, its high impedance at cutoff would be transformed to short circuit (or nearly so) at combining node P3 513, because a circuit with ±90° phase acts as a quarter wave impedance-inverting transformer. The result short on node P3 513 would severely degrade performance of amplifier 500. However, with peaking amplifier 573 connected to the 0° arm of coupler 900 as described, amplifier 573 presents high impedance at port P3 513 when cutoff. A modest impedance mismatch results at port P1 911, however the Doherty amplifier can maintain good efficient performance over a wide range of output powers.

FIG. 10 is a circuit diagram of another innovative dual-T combining network 1000. Ports 1011-1013 correspond to nodes 511-513 of FIG. 5. A first T-network, formed by inductor C1 1041, capacitor L1 1031, and inductor C2 1042, can match output impedance of an amplifier coupled to port 1011 and can provide about +90° phase shift (or in a range) 80°-100° from port P1 1011 to port P3 1013. A second T-network formed by inductor C3 1043, capacitor L2 1032, and capacitor L3 1033 can provide a small phase shift (e.g. between −10° and)+10° from port P2 1012 to port P3 1013. That is, phase delay through inductor L3 1033 and phase advance through capacitor C3 1043 can be arranged to cancel each other. With input phase of 0° at amplifier 572 or at port P1 1011, and input phase of +90 at amplifier 573 or port P2 1012 (as noted in FIG. 5), main and carrier signals both reach port 1013 (513) in-phase, e.g. at 90° phase, adding together as desired.

Like the first T-network, the second T-network can also match the output impedance of an amplifier coupled to port 1012. Still further, the dual-T network has enough degrees of freedom to support a step up in impedance so that low output impedances Z1, Z2 of amplifiers coupled to ports 1011, 1012 can be transformed to match a higher output impedance Z3 of a load on port 1013. That is, combiner 1000 can also be designed to provide |Z3|>max (|Z1|, |Z2|).

Considerations for connecting main amplifier 572 to input port P1 1011 and peaking amplifier 573 to input port P2 1012, instead of the other way around, are similar to those discussed above for combiner 900.

The +90° insertion phase provided by combiner 1000 cannot be implemented practically with waveguides, transmission lines, or their discrete component analogs. This is because transmission lines (e.g. waveguides) inherently provide phase lag (negative insertion phase). An attempt to obtain+90° phase shift as a transmission line having−270° insertion phase would be three times as bulky as a −90° transmission line and would offer considerably narrower operating bandwidth. Thus, innovative combiner 1000 offers additional design flexibility not previously achievable.

Combiners 900, 1000 each exhibit the compactness of a discrete component network, without the drawbacks of combiners 474, 600, 700, 800. Particularly, doing impedance step-up directly, rather than step-down followed by a bigger step up, combiners 900, 1000 can achieve better frequency response than the comparative combiners, and can also exhibit lower loss. A second series stage for impedance step-up (e.g. similar to section 476) can be omitted. Performance results and comparisons are provided herein.

With impediments to adoption removed, compact and efficient Doherty amplifiers can be implemented with combiners such as 900, 1000. In some applications, output of a main amplifier similar to 572 can be coupled to input port P1 911, 1011, and output of a peaking amplifier similar to 573 can be coupled to input port P2 912, 1012. A resulting system similar to 500 can be implemented as a mobile phone or other RF transmitter product 305.

Combiners 900, 1000 can also be applied as combiners or splitters in other applications.

In some examples, combiners 900, 1000 can be implemented using lossless reactive elements. Examples of combiner 900, 1000 can provide step-up in impedance, phase shift magnitude at most 10° in one arm, and optionally phase shift magnitude between 80°-100° in the other arm, over a targeted operating frequency range. The targeted frequency range can have a width of 15% about a center frequency in a range 1-5 GHz, or at least 1 GHz.

### Example Principle of Operation

The suitability of combiners 900, 1000 for Doherty amplifier applications is dependent on having near zero phase shift in one arm of the combiner. However, contrary to the desired characteristics for a Doherty amplifier combiner, T-networks are generally known in the art to have high series impedance and low gain as the insertion phase approaches zero. FIGS. 11-12 illustrate this.

FIG. 11 is a chart 1100 showing insertion gain vs. insertion phase for a low-pass T-network, the output of which lags the input, corresponding to negative insertion phase. Graph 1110 is seen to asymptotically approach a gain of 0 (or, −∞ dB) as the insertion phase approaches zero.

FIG. 12 is a chart 1200 showing insertion gain vs. insertion phase for a high-pass Tee network, the output of which leads the input, corresponding to positive insertion phase. Graph 1210 is seen to asymptotically approach a gain of 0 (or, −∞ dB) as the insertion phase approaches zero.

For this reason, a skilled artisan would not expect that a topology based on T-networks would be able to realize the performance characteristics of combiners 900, 1000, let alone that these combiners would exhibit superior performance over bandwidth as described further herein.

To understand why combiners 900, 1000 are feasible, it can be helpful to consider another model of these circuits. FIG. 13 illustrates a model of a dual-T combining network 1300 incorporating phantom shunt reactances 1362, 1364, shown as dashed outline.

In FIG. 13, ports P1-P3 1311-1313 correspond to ports P1-P3 911-913, 1011-1013 of FIGS. 9-10. A first T-network is formed by series reactances X1 1351, X2 1352 and shunt susceptance B1 1361. A second T-network is formed by series reactances X3 1353, X4 1354 and shunt susceptance B3 1363. These T-networks are realized in combiners 900, 1000 with inductors and capacitors. As shown, the two T-networks are loaded with respective shunt susceptances 1362, 1364, and are also joined at port P3 1313.

Consider an implementation similar to combiner 900, with a low-pass first T-network. With inductors X1 1351, X2 1352 and capacitors B1 1361, B2 1362, there are two LC subsections, whose phase shifts add and can be set to obtain −90° total phase shift from port P1 1311 to port P3 1313. Then, with inductor X3 1353, capacitors B3 1363, X4 1354, and another inductor 1364, there is an LC section followed by a CL section, whose respective negative and positive phase shifts can be set to cancel, to obtain 0° phase shift from port P2 1312 to port P3 1313 as desired, without significant attenuation. That is, unlike a three-element T-network, the four-element network 1353, 1363, 1354, 1364 is not constrained by FIGS. 11-12.

Further, the susceptance of inductor 1364 can be set to cancel the susceptance of capacitor 1362, so that their parallel combination is an open circuit, meaning that both can be removed from the circuit. For this reason, reactive elements 1362, 1364 are labeled as having complementary susceptance B2 and −B2, and are shown as phantom components in dashed outline, because they are not physically realized in combiner 900.

Similar reasoning is applicable to combiner 1000, with the phantom reactive elements being an inductor 1362 and its complementary capacitor 1364.

### Example Differential Amplifier

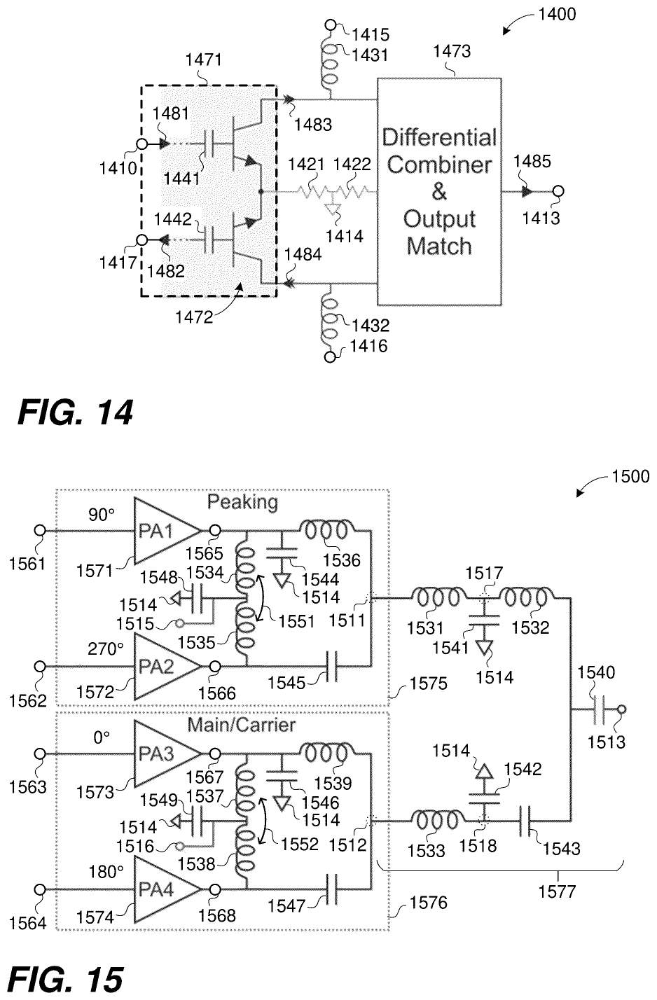

FIG. 14 is a simplified schematic diagram 1400 of a differential amplifier 1471 coupled to an output combining network 1473. Diagram 1400 can be seen in context of amplifier system 300, with input signals 1481, 1482 corresponding to amplifier input signals 331, 332 of FIG. 3, and output signal 1485 corresponding to combiner output 338 of FIG. 3. For convenience of illustration, a counterpart to splitter 371 is not shown in FIG. 14.

Differential input signals 1481, 1482 can be received at input ports 1410, 1417. Arrows 1481, 1482 are shown with directions indicating an instantaneous RF current in each respective arm. Differential input signals 1481, 1482 are coupled through DC blocking capacitors 1441, 1442 to differentially coupled amplifier 1472. Dotted lines on signals 1481, 1482 indicate optional presence of additional passive components not shown in this simplified schematic.

Differential output signals 1483, 1484 flow from amplifier module 1471 to combining network 1473, which can combine differential inputs into a single-ended output signal 1485, and can additionally provide impedance matching, e.g. between low output impedances of amplifier module 1471 and a higher input impedance of a load (not shown) coupled to output port 1413. Combining network 1473 can be implemented as a SILC, but this is not a requirement and other couplers can also be used.

FIG. 14 also shows bias supply terminals 1415, 1416 coupled by RF blocking inductors 1431, 1432 to output terminals of amplifier module 1471. Optional connections to grounding node 1414 via resistors 1421, 1422 are also shown. These connections are sometimes dubbed a “ground path”. In an ideal differential amplifier, ground currents may be zero and, in some examples, resistors 1421, 1422 can be omitted. In other examples, resistors 1421, 1422 can be retained.

One or more differential amplifiers as shown in FIG. 14 can be used as building blocks for a differential Doherty amplifier, as described herein.

### Example Differential Doherty Amplifier

FIG. 15 is a circuit diagram 1500 of two differential amplifiers coupled to an output combining network in an innovative differential Doherty amplifier configuration. As illustrated, each differential amplifier 1575, 1576 can be similar to the differential amplifier of FIG. 14, and combining network 1577 can be similar to combiner 900. Like amplifier 500, the system of FIG. 15 can also be seen as a recursive instance of amplifier 360 and combiner 374 of FIG. 3.

Differential amplifier 1576 is shown having input ports 1563, 1564 corresponding to ports 1410, 1417 of FIG. 14, and output node 1512 corresponding to port 1413. Similar to FIG. 14, input signals at ports 1563, 1564 are out-of-phase and are marked 0° and 180°. Power amplifiers PA3 1573, PA4 1574 together correspond to differential amplifier 1472 of FIG. 14, and can operate in class A/B or class B mode (always ON), serving as main amplifiers. Outputs of amplifiers PA3 1573, PA4 1574 can be combined with a SILC as shown, comprising in one arm shunt inductor 1537, shunt capacitor 1546, and series inductor 1539. In the other arm, the SILC can include shunt inductor 1538 and series capacitor 1547. Inductors 1537, 1538 can be magnetically coupled as indicated by arrow 1551. The combined output is presented at node 1512, which is corresponds to combiner port 912 of FIG. 9.

As illustrated, the common node of inductors 1537, 1538 is a grounding node, bypassed to ground 1514 through bypass capacitor 1549, and also serving as a bias supply terminal 1516. Thus, bias terminal 1516 serves a similar function as bias terminals 1415, 1416, and inductors 1537, 1538 serve as RF blocks for bias current, similar to inductors 1431, 1432.

Differential amplifier 1575 is arranged similarly to differential amplifier 1576. Input ports 1561, 1562 correspond to ports 1410, 1417 of FIG. 14, and output node 1511 corresponds to port 1413. Out-of-phase input signals at ports 1561, 1562 are marked 90° and 270° respectively; they are in quadrature to input signals at ports 1563, 1564. Power amplifiers PA1 1571, PA2 1572 together correspond to differential amplifier 1472 of FIG. 14, and can operate in class C mode as a peaking amplifier. Outputs of amplifiers PA1 1571, PA2 1572 can be combined with a SILC as shown, comprising inductors 1534-1536 and capacitors 1544-1545 similar to the SILC in amplifier module 1576. Inductors 1534, 1535 can be magnetically coupled as indicated by arrow 1551. The combined output is presented at node 1511, which corresponds to combiner input port 911 of FIG. 9. Similar to module 1576, differential amplifier module 1575 includes bias terminal 1515 bypassed to ground 1514 through bypass capacitor 1548. Blocking capacitor 1540 provides DC isolation between bias terminal 1515 and output port 1513.

Combiner 1577 is similar to combiner 900, providing impedance step-up from input nodes 1511, 1512 to output node 1513. The upper T-network (inductors 1531, 1532 and capacitor 1541) provides approximately −90° phase shift from node 1511 to output port 1513, while the lower T-network (inductor 1533 and capacitors 1542, 1543) provides approximately 0° phase shift from node 1512 to output port 1513. Thus for the input phasing shown, both main and peaking signals reach blocking capacitor 1540 and output port 1513 in phase. As shown, the lower T-network (with about 0° phase shift) is coupled to the main differential amplifier 1576.

Considerations for how to connect main and peaking amplifiers 572, 573 to input ports P1, P2 were discussed above in context of combiner 900. Notably, the amplifier connectivity is reversed for the differential Doherty amplifier in FIG. 15. The reason for this is that a SILC combiner has an insertion phase of about +90° between input nodes 1565, 1566 and output node 1511. Thus, when peaking amplifiers 1571, 1572 are in a low output power cutoff state, their high output impedances are transformed to a low output impedance at node 1511. If the peaking amplifier was connected to the 0° arm of combiner 1577, the output node 1513 would be effectively shorted to ground, severely degrading performance of the illustrated Doherty amplifier. However, connected as shown, with the peaking amplifiers coupled to the −90° phase arm of combiner 1577, the low impedance at node 1511 is transformed again to high impedance at output port 1513. Other than a modest impedance mismatch seen at port 1512, the Doherty amplifier continues to operate efficiently as output power is reduced.

Numerous variations and extensions of the system of FIG. 15 can be implemented within scope of the disclosed technologies. As illustrated, combiner 1577 is an instance of combiner 900. In a variation, with suitably adjusted phases of the input signals at ports 1561-1564, combiner 1577 can be replaced with an instance of combiner 1000. For example, the phases of inputs 1561-1562 can be swapped, while retaining the phases of inputs 1563-1564. A load similar to 370 or 521 can be coupled to output port 1513. Other features described in context of amplifier 500 can also be applied to the system of FIG. 15.

The system of FIG. 15 includes a 4:1 combiner having input ports 1565-1568 and output port 1513. This combiner incorporates a first differential coupler having input ports 1565, 1566 and output port 1511; a second differential combiner having input ports 1567, 1568 and output port 1512; and a quadrature coupler having input ports 1511, 1512 and output port 1513. At least one of the first or second differential couplers can be realized as a SILC. The quadrature coupler can be realized as an innovative coupler according to FIGS. 9-10. Input impedances at ports 1565-1568 can be respectively matched to output impedances of amplifiers PA1-PA4 1571-1574, and output impedance at port 1513 can be matched to a load (not shown) coupled to port 1513.

The system of FIG. 15 can be augmented with one or more drivers and/or a splitting network to provide input signals at ports 1561-1564 with suitable phasing for a differential Doherty amplifier, e.g. as shown. Like amplifier 500, the system of FIG. 15 can be advantageously incorporated in mobile phones, other communication terminals, or other products 305.

### Example Design Curves

With reference to FIG. 5, amplifiers PA1 572 and PA2 573 can be designed with equal output impedances, in which case efficiency (PAE) exhibits a primary peak and a secondary peak. The primary peak is at maximum output power (0 dB backoff) with both main and peaking amplifiers contributing half the output power. The secondary peak is at −6 dB backoff, with peaking amplifier OFF and having high output impedance. At the secondary peak, main amplifier PA1 572 contributes 3 dB below its maximum power output (because of impedance mismatch at node 511, which in turn is due to the high output impedance of PA2 573 in this state).

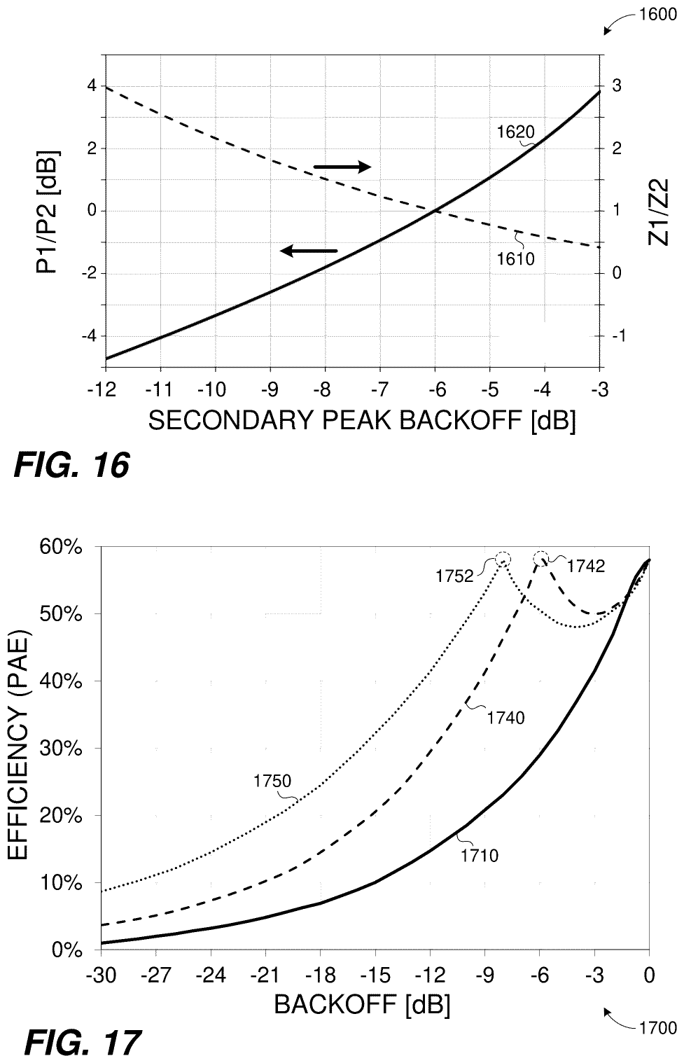

However, in some applications, it may be desirable to have the secondary peak at a backoff other than-6 dB. FIG. 16 is a chart 1600 depicting example design curves for variable balance between main and peaking Doherty amplifiers. Given any secondary peak backoff (along the horizontal axis), graph 1610 provides a ratio Z1/Z2 between output impedance Z1 of a main amplifier and output impedance Z2 of a peaking amplifier. Graph 1620 provides a ratio P1/P2 between main output power P1 and peaking amplifier output power P2 at 0 dB backoff, which is maximum output power and also the primary peak in efficiency.

Knowledge of impedances Z1, Z2, Z3 (satisfying the ratio Z1/Z2 determined from graph 1610) can enable a skilled artisan to design a combiner 900 or 1000 as described further herein.

Knowledge of required maximum output power (P1+P2), the ratio P1/P2 (from graph 1620), and the impedance ratio Z1/Z2 can also enable a skilled artisan to design amplifiers PA1 572 and PA2 573. However, the design of an amplifier circuit 572, 573 is beyond the scope of this disclosure.

### Example Doherty Efficiency

FIG. 17 is a chart 1700 depicting examples of efficiencies of a single power amplifier and Doherty amplifiers coupled according to the disclosed technologies. Graph 1710 is a replica of graph 210 of FIG. 2, showing power amplifier efficiency (PAE) of a representative power amplifier module such as 572 of FIG. 5. Graphs 1740, 1750 shows efficiency of a Doherty amplifier according to FIG. 5, with combiner 900 realizing combiner 574. Graph 1740 is for a configuration having secondary efficiency peak 1742 at −6 dB backoff, while graph 1750 is for a configuration having secondary efficiency peak 1752 at −8 dB backoff. Comparison with the probability distributions of modulated waveforms 220, 230 of FIG. 2 shows that the Doherty amplifiers represented in graphs 1740, 1750 have approximately double the efficiency of a single amplifier (graph 1710) over the power levels most utilized by common QAM or WCDMA modulation schemes.

### Example Method

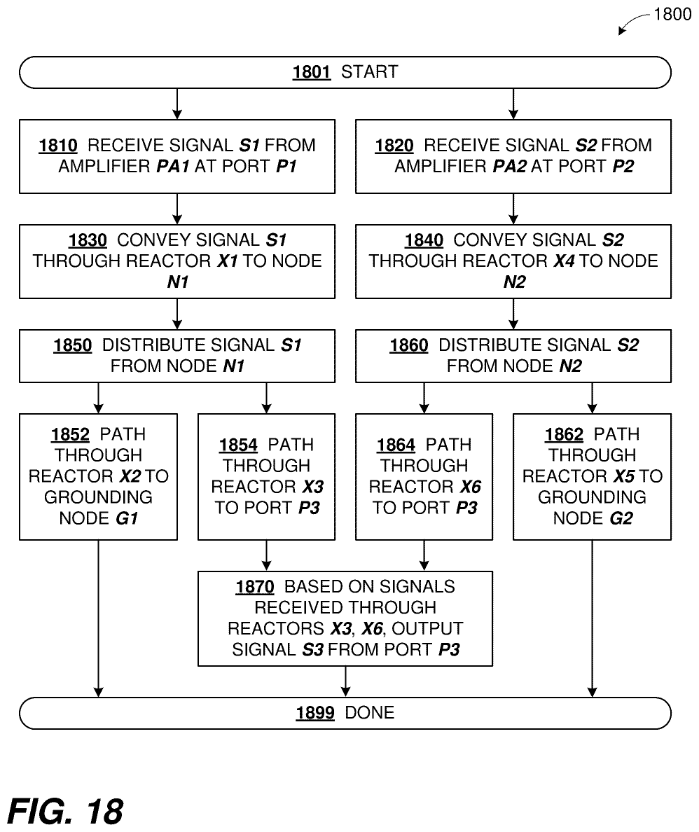

FIG. 18 is a flowchart 1800 of an example method. This method follows a signal propagating through paths of an innovative combiner. The combiner can be similar to couplers 900, 1000, 1577 described herein, and its ports P1-P3 can be similar to corresponding ports P1-P3 described for those couplers. The instant method is described in context of FIGS. 5, 9, 10, and 15 for convenience of illustration, however the method is not so limited and can be implemented with other combiners as well.

The method commences at start block 1801. At process block 1810, signal S1 can be received from a first upstream device, such as amplifier PAI (similar to 572, 1575), at port P1 (511, 911, 1011, 1511) of an instant combiner (574, 900, 1000, 1577). At block 1820, a signal S2 can be received from a second upstream device, such as amplifier PA2 (573, 1576), at port P2 (512, 912, 1012, 1512) of the instant combiner. The signals can be RF signals or other oscillatory signals.

At block 1830, signal S1 can be conveyed from port P1 through reactor X1 (931, 1041, 1531) to intermediate node N1 (917, 1017, 1517). At block 1850, signal S1 can be distributed from node N1: at block 1852, a portion of signal S1 can be conveyed via reactor X2 (941, 1031, 1541) to grounding node G1 (914, 1014, 1514); and at block 1854, another portion of S1 can be conveyed via reactor X3 (933, 1042, 1532) to port P3 (513, 913, 1013, 1513). In examples, distribution at block 1830 can occur instantaneously and continuously over the duration of signal S1 and, correspondingly, process blocks 1852, 1854 can be performed simultaneously.

Similarly, at block 1840, signal S2 can be conveyed from port P2 through reactor X4 (933, 1043, 1533) to intermediate node N2 (918, 1018, 1518). At block 1860, signal S2 can be distributed from node N2: at block 1862, a portion of signal S2 can be conveyed via reactor X5 (942, 1032, 1542) to grounding node G2 (914, 1014, 1514); and at block 1864, another portion of S2 can be conveyed via reactor X6 (943, 1033, 1543) to port P3. In examples, distribution at block 1840 can occur instantaneously and continuously over the duration of signal S1 and, correspondingly, process blocks 1862, 1864 can be performed simultaneously.

At block 1854, a portion of signal S1 can be received at combiner port P3 via reactor X3, and at block 1864, a portion of signal S2 can be received at combiner port P3 via reactor X6. The method flows from blocks 1854, 1864 to block 1870, where the signal portions received at port P3 (513, 913, 1013, 1513) can be combined to output a third signal S3 from combiner port P3 (513, 913, 1013, 1513). In examples, signal S3 can be outputted toward an antenna or other load (521). The outputted signal can be transmitted as a radio signal.

Conveyance of signal portions to ground, at blocks 1852, 1862, and the output of signal S3 at block 1870 complete the method. All branches of flowchart 1800 proceed to block 1899, and the method terminates.

The insertion phase between (i) input signal S2 at port P2 and (ii) output signal S3 at port P3 can have a magnitude less than 10° over a target operating frequency range. Concurrently, the output impedance at port P3 can be greater than input impedances at each of ports P1, P2.

Numerous variations and extensions of this method can be implemented within scope of the disclosed technologies.

In some examples, amplifiers PA1, PA2 can be main and peaking amplifiers of in a Doherty configuration, but this is not a requirement, and the method can be practiced with other compound amplifier configurations and applications as well. The amplifiers and combiner can be part of a communication terminal, such as a cell phone. In such applications, signals S1, S2 can be received simultaneously, but this is not a requirement and, in other applications a combiner can perform the instant method as a multiplexer, with only one of signals S1, S2 active at any given time.

In some examples, signals S1, S2 can be present simultaneously and the respective portions can be summed at block 1870. In other examples, signals S1, S2 can be present at distinct times and the respective portions can be multiplexed at block 1870.

In a common Doherty amplifier configuration, the power ratio between signals S1, S2 can be 1:1 (0 dB), with a phase offset of 90°, and the Doherty amplifier can exhibit a peak in efficiency at a backoff of −6 dB, but this is not a requirement, and the method can be used with combiners for other Doherty configurations as well.

Other features described in context of FIGS. 3, 5, 9, 10, and 15, or elsewhere herein, can also be applicable to the method of FIG. 18, or the environment in which this method is performed.

### Example Design

Three examples are worked out below: one example of combiner 900 of FIG. 9 with a secondary efficiency peak at −8 dB backoff; and a second example of combiner 1000 of FIG. 10 with a secondary efficiency peak at −6 dB backoff. The third example is combiner 1577 of the Differential Doherty amplifier of FIG. 15, also with secondary efficiency peak at −6 dB backoff.

1. Design Inputs: Z1, Z2, Z3, dBR, F0

Initially, design inputs are provided as shown in Table 1. Z1, Z2 are the amplifier output impedances on ports P1, P2 of FIGS. 9, 10 and Z3 is the load impedance on port P3. dBR is the ratio of maximum power available at port P1 to that available at P2, in dB. As described herein, the ratios of Z1/Z2 and dBR are chosen in accordance with FIG. 16, based on the desired secondary efficiency peak.

TABLE 1
Design Inputs

| Parameter | Units | Ex. 1 (900) | Ex. 2 (1000) | Ex. 3 (1577) |
|---|---|---|---|---|
| Z1 | Ω | 8 | 8 | 32.5 |
| Z2 | Ω | 5.29 | 8 | 32.5 |
| Z3 | Ω | 50 | 50 | 50 |
| dBR | dB | −1.8 | 0.0 | 0.0 |
| F0 | MHz | 1867.5 | 1867.5 | 1867.5 |

### 2. Intermediate Variables:

For calculation convenience, it can be helpful to pre-compute angular frequency ω=2π·F0; power ratio P1/P2=10^{(dBR/10)}; and conductances Gi=1/Zi for i={1, 2, 3}. These values are shown in Table 2a.

TABLE 2a
Intermediate Values

| Parameter | Units | Ex. 1 (900) | Ex. 2 (1000) | Ex. 3 (1577) |
|---|---|---|---|---|
| ω | s⁻¹ | 1.173E+10 | 1.173E+10 | 1.173E+10 |
| P1/P2 | | 0.66069 | 1.0 | 1.0 |
| G1 | [symbol] | 0.125 | 0.125 | 0.03077 |
| G2 | [symbol] | 0.125 | 0.18904 | 0.03077 |
| G3 | [symbol] | 0.020 | 0.020 | 0.020 |

Then, we can introduce components of an intermediate admittances which can aid calculation of the shunt and series circuit elements of the target combiner circuits. For intermediate YIL, Y2L having components YiL=GiL+j BiL, we can calculate GiL directly (Equations 1-2 below), while BiL can be expressed in terms of a free parameter Bv (corresponding to B2 in FIG. 13). Index i=1, 2 corresponds to the T-networks connected to ports P1, P2 respectively.

$$G 1 L = G 3 / ( 1 + \frac{P 2}{P 1} ) \qquad ( 1 )$$

$$G 2 L = G 3 / ( 1 + \frac{P 1}{P 2} ) \qquad ( 2 )$$

$$B 1 L = Bv \qquad ( 3 )$$

$$B 2 L = - Bv + B 3 = - Bv ( for B 3 = 0 ) \qquad ( 4 )$$

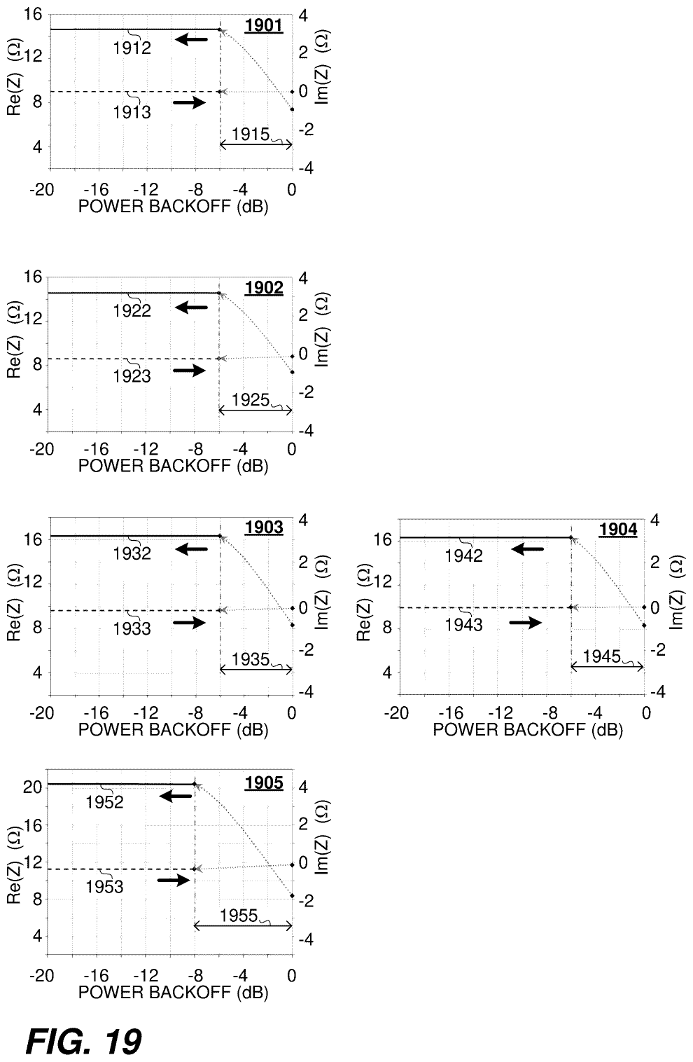

The free parameter Bv can be tuned by evaluating component values (as described in this section) and performance parameters (e.g. as shown in FIGS. 19-22) at a succession of trial values of Bv, and choosing one value of Bv among several tested. Trial values of Bv can be selected based on the minimum and maximum values of the set {G1, G2, G3, G1L, G2L}. To illustrate for Ex. 1, the minimum and maximum conductance values of the set are about 0.008 and 0.125. An initial coarse scan can be performed from half the minimum value to twice the maximum value, e.g. Bv={0.004, 0.016, 0.064, 0.250}, with progressively finer scans e.g. Bv={0.016, 0.032, 0.048, 0.064} and so forth. Alternatively, binary search or curve fitting on a figure of merit can be used to converge more quickly on an optimum value of Bv. Evaluation of performance parameters can incorporate parasitic resistance (e.g. finite Q values) of the calculated components. In examples, positive values of Bv can be evaluated for combiners 900, 1577 to obtain a positive susceptance for a shunt capacitance element, and negative values of Bv can be evaluated for combiner 1000 to obtain a negative shunt susceptance corresponding to an inductor. Equations 4 (above) and 5-6 (below) are initially presented in a general form including B1, B2, or B3, which are given by Bi=Im (1/Zi) for i=1 . . . 3. For the real impedances Zi in the present examples, Bi=0, and each of these equations can be simplified as shown.

Equations 5-6 provide the shunt susceptances in the ∓90° and 0° phase shift arms respectively. In equation 5, the upper sign applies to a low-pass upper T-network providing −90° phase shift (combiners 900, 1577), while the lower sign applies to a high-pass upper T-network providing +90° phase shift.

$$B 1 b = ∓ \frac{B 1 \cdot B 1 L - G 1 \cdot G 1 L}{\sqrt{G 1 \cdot G 1 L}} = \pm \sqrt{\frac{G 1}{G 1 L}} \qquad ( 5 )$$

$$B 2 b = - \frac{B 2 \cdot G 2 L + G 2 \cdot B 2 L}{\sqrt{G 2 \cdot G 2 L}} = Bv . \sqrt{\frac{G 2}{G 2 L}} \qquad ( 6 )$$

As a matter of notation, the suffixes a, b, c denote the component order in each T-network: “a” for the series element nearest respective input port P1, P2; “b” for the shunt element; and “c” for the series element nearest output port P3.

These intermediate values are shown in Table 2b for the present examples.

TABLE 2b
Intermediate Values

| Parameter | Units | Ex. 1 (900) | Ex. 2 (1000) | Ex. 3 (1577) |
|---|---|---|---|---|
| G1L | [symbol] | 0.00796 | 0.010 | 0.010 |
| G2L | [symbol] | 0.01204 | 0.010 | 0.010 |
| B1c | [symbol] | 0.03154 | −0.03536 | 0.01754 |
| Bv | [symbol] | 0.02480 | −0.02130 | 0.00997 |
| B2c | [symbol] | 0.09825 | −0.07531 | 0.01749 |

The values of GiL, BiL can be collected as complex YiL=GiL+j BiL, and inverted to obtain complex ZiL=1/YIL, which has real and imaginary parts RiL, XiL. These values are shown in Table 2c.

TABLE 2c
Intermediate Values

| Parameter | Units | Ex. 1 (900) | Ex. 2 (1000) | Ex. 3 (1577) |
|---|---|---|---|---|
| Y1L | [symbol] | 0.00796 + | 0.0100 − | 0.0100 + |
| | | j 0.0248 | j 0.0213 | j 0.00997 |
| Z1L | Ω | 11.730 − | 18.061 + | 50.150 − |
| | | j 36.559 | j 38.469 | j 50.000 |
| R1L | Ω | 11.730 | 18.061 | 50.150 |
| X1L | Ω | −36.559 | 38.469 | −50.000 |
| Y2L | [symbol] | 0.01204 − | 0.0100 + | 0.0100 − |
| | | j 0.0248 | j 0.0213 | j 0.00997 |
| Z2L | Ω | 15.844 + | 18.061 + | 50.150 − |
| | | j 32.628 | j 38.469 | j 50.000 |
| R2L | Ω | 15.844 | 18.061 | 50.150 |
| X2L | Ω | 32.628 | 38.469 | −50.000 |

Finally, the series reactance values Xia, Xic can be determined for both T-networks according to

$$X i a = \frac{1}{B i b} \cdot ( 1 - \sqrt{\frac{R i}{R i L} - {( Bib \cdot Ri )}^{2}} ) - Xi = \frac{1}{B i b} \cdot ( 1 - \sqrt{\frac{R i}{R i L} - {( Bib \cdot Ri )}^{2}} ) \qquad ( 8 )$$

$$Xic = \frac{1}{B i b} \cdot ( 1 - \sqrt{\frac{R i L}{R i} - {( Bib \cdot RiL )}^{2}} ) - X i L$$

Equation 7 has been simplified for real amplifier output impedances, Xi=0. Evaluation of Equations 7-8 results in the values are shown in Table 2d.

TABLE 2d
Intermediate Values

| Parameter | Units | Ex. 1 (900) | Ex. 2 (1000) | Ex. 3 (1577) |
|---|---|---|---|---|
| X1a | Ω | 6.774 | −11.244 | 24.606 |
| X1c | Ω | 31.708 | −28.284 | 57.009 |
| X2a | Ω | 7.609 | −9.523 | 24.583 |
| X2c | Ω | −30.145 | 33.669 | −43.121 |

### 3. Component Values:

With the series reactance values X and shunt susceptance values B determined above (Tables 2b, 2d), calculating component values is straightforward, using: L=X/ω or C=−1/ωX for the series elements, according to whether the reactance is positive (inductor) or negative (capacitor); and C=B/ω or L=−1/ωB for the shunt elements, according to whether the susceptance is positive (capacitor) or negative (inductor). These values are shown in Table 3.

TABLE 3
Component Values

| Parameter | Units | Ex. 1 (900) | Ex. 2 (1000) | Ex. 3 (1577) |
|---|---|---|---|---|
| C1 941, 1541 | pF | 2.688 | | 1.495 |
| L1 1031 | nH | | 2.410 | |
| C2 942, 1542 | pF | 8.374 | | 1.490 |
| L2 1032 | nH | | 1.132 | |
| L1 931, 1531 | nH | 0.5773 | | 2.097 |
| C1 1041 | pF | | 7.579 | |
| L2 932, 1532 | nH | 2.702 | | 4.858 |
| C2 1042 | pF | | 3.013 | |
| L3 933, 1533 | nH | 0.6484 | | 2.095 |
| C3 1043 | pF | | 8.949 | |
| C3 943, 1543 | pF | 2.827 | | 1.976 |
| L3 1033 | nH | | 2.869 | |

### 4. SILC Design for Differential Doherty Combiner

The 4:1 combiner of FIG. 15 has 2 SILC combiners upstream of nodes 1511, 1512. To calculate the SILC component values, a design procedure provided in U.S. Pat. No. 11,742,819 can be used, for input design parameters Z1, Z2, Z3, ρ, F0, and K. Considering the combiner in module 1575, the following values can be used: Z1=Z2=16Ω as output impedances of amplifiers 1571, 1572; Z3=32.5 Ω to match input 1511 of combiner 1577; p=1 (equal power from amplifiers 1571, 1572); F0=1867.5 MHz (same as for combiner 1577 in Example 3 above); and K=0.7 for the magnetic coupling factor 1551 between inductors 1534, 1535. The same design inputs can be used for amplifier module 1576. Table 4 shows the resulting component values.

TABLE 4
SILC Component Values

| Module 1575 | | Module 1576 | |
|---|---|---|---|
| Component | Value | Component | Value |
| 1534 | 1.617 nH | 1537 | 1.617 nH |
| 1544 | 5.285 pF | 1546 | 5.285 pF |
| 1536 | 2.748 nH | 1539 | 2.748 nH |
| 1535 | 1.617 nH | 1538 | 1.617 nH |
| 1545 | 2.643 pF | 1547 | 2.643 pF |

The matching impedance value between SILC and Doherty combiner designs, 32.5Ω in these examples, can be a free parameter selected using similar principles as for Bv above. While it is generally desirable for the impedances at ports 1511, 1512 to be between the output impedances of the amplifiers 1571-1574 and the load impedance on port 1513, this value can be tuned to obtain optimized performance.

The design procedure described above can provide a target value of SILC output impedance at nodes 1511, 1512 at a mid-band frequency. Because of frequency variation of reactive components, and further because of non-ideal nature of practical components used, the actual output impedance at the band edges can vary from the target value. Accordingly, in some examples, further improvement of the overall characteristics of a 4:1 differential Doherty combiner, as in FIG. 15, can be obtained by adjusting component values about those determined by the design procedure described above. In this way, a chosen performance parameter, such as insertion loss at the band edges, can be further optimized.

In some examples, free parameters can be tuned to minimize worst case loss over a target operating bandwidth, or size of the realized combiner. The illustrated calculations can be extended to incorporate circuit variations according to well-known principles of circuit analysis and simultaneous equations.

### Example Performance

FIGS. 19-22 provide comparisons of several performance parameters between different combining networks in Doherty amplifier applications. These parameters include input impedance, output impedance, and insertion loss. Configurations compared include the classic Doherty combiner 474 of FIG. 4, and combiners 600, 900, 1000 also used in Doherty amplifiers 400, 500 with similarly configured sources and loads. Most charts reflect designs with secondary peak efficiency at a backoff of −6 dB, and a few charts reflect designs with secondary peak efficiency at a backoff of −8 dB.

Some charts demonstrate performance over a band 1710-2025 MHz, which covers a few bands of interest in cellular telephony. This band has a width that is 16.9% of its center frequency 1867.5 MHz. Other bands of practical interest can have similar widths and can be covered with similar performance using examples of the disclosed technologies.

As demonstrated below, innovative combiners shown in FIG. 9, 10, or 15 have markedly superior performance characteristics as compared to the classic Doherty combiner 474 shown in FIG. 4 or its discrete analogs shown in FIGS. 6-8. In addition to Doherty amplifiers, the illustrated performance characteristics can be advantageously employed in other applications—e.g. anywhere quadrature combiners or splitters are used.

### 1. Input and Output Impedance Variation Over Operating Power Range

FIG. 19 is a chart series 1901-1905 depicting input impedance vs. backoff power for several Doherty amplifier configurations. Real part (solid line) and imaginary part (dashed line) of the input impedance are referenced to the left- and right-hand vertical axes respectively, as indicated by bold arrows for convenience. The input impedance shown is for a combiner input providing about +90° phase shift, e.g. nodes 411, 511, 1511 of FIGS. 4, 5, 15, or ports 611, 911, 1011 of their respective Figures.

As described herein, a Doherty amplifier provides variable combination of a main signal and a peaking signal as the output power is varied. At maximum power (0 dB backoff), the peaking amplifier is fully ON, both main and peaking amplifiers contribute their maximum power, and the Doherty amplifier can exhibit a primary peak in efficiency. As output power drops, the peaking amplifier contribution drops, its output impedance increases and, due to coupling between combiner input ports, an impedance mismatch develops in the main signal path. At a specified backoff power, the peaking amplifier is effectively OFF, and the Doherty amplifier can exhibit a secondary peak in efficiency. For increasing (more negative) backoff, the peaking amplifier remains OFF.

The backoff power corresponding to the secondary peak is shown as a dash-dot line in charts 1901-1905. The maximum power point (0 dB backoff) and the region to the left of the dash-dot lines are amenable to analytic calculation, because the peaking amplifier is fully ON or fully OFF. However, in the transition regions (e.g. 1915, 1925, 1935, 1945, 1955), circuit characteristics depend on non-linear behavior of the peaking amplifier and can be complex. Accordingly, the impedance behavior in the transition regions is shown schematically as dotted lines connecting the operating points at the primary and secondary efficiency peaks.

On chart 1901, graphs 1912, 1913 show real and imaginary parts of input impedance at mid-band frequency, as a function of output power backoff, for a classic Doherty amplifier according to FIG. 4. Both amplifiers PA1 471, PA2 472 have output impedances of 8Ω, and the combiner is configured to drive a 50Ω load. The secondary efficiency peak is at a backoff of −6 dB. The real part Re(Z1) 1912 of combiner input impedance varies from about 7.3Ω at maximum power to about 14.5Ω at and below the secondary efficiency peak. Imaginary part Im (Z1) 1913 is small, with magnitude on the order of 0.1Ω or less. Deviation from ideal values of 8Ω and 16Ω are mainly due to parasitic resistance of non-ideal transmission line sections 475, 476.

On chart 1902, graphs 1922, 1923 show real and imaginary parts of input impedance at mid-band frequency, as a function of output power backoff, for a Doherty amplifier with discrete combiner 600 replacing combiner 474 of FIG. 4. Both amplifiers PA1 471, PA2 472 have output impedances of 8Ω, and the combiner is configured to drive a 50Ω load. The secondary efficiency peak is at a backoff of −6 dB. The real part Re(Z1) 1922 of combiner input impedance varies from about 7.3Ω at maximum power to about 14.5Ω at and below the secondary efficiency peak. Imaginary part Im (Z1) 1923 is small, with magnitude up to about 0.3Ω. These values are similar to those of chart 1901. Again, deviation from ideal values of 8Ω and 16Ω are mainly due to parasitic resistance of non-ideal reactive elements in combiner 600.

On chart 1903, graphs 1932, 1933 show real and imaginary parts of input impedance at mid-band frequency, as a function of output power backoff, for a Doherty amplifier with innovative combiner 900 realizing combiner 574 of FIG. 5. Both amplifiers PA1 571, PA2 572 have output impedances of 8Ω, and the combiner is configured to drive a 50Ω load. The secondary efficiency peak is at a backoff of −6 dB. The real part Re(Z1) 1932 of combiner input impedance varies from about 8.3Ω at maximum power to about 16.5Ω at and below the secondary efficiency peak. Imaginary part Im (Z1) 1933 is small, with magnitude up to about 0.2Ω. The real impedance is maintained closer to ideal values of 8 Ω and 16Ω, as compared to the classic Doherty shown in chart 1901, or its discretized analog shown in chart 1902.

Chart 1904 shows real and imaginary parts of input impedance for a configuration similar to that of chart 1903, however using innovative combiner 1000 rather than 900. The real part Re(Z1) 1942 of combiner input impedance varies from about 8.3Ω at maximum power to about 16.5Ω at and below the secondary efficiency peak. Imaginary part Im (Z1) 1943 is small, with magnitude on the order of 0.1 Ω or less. Like combiner 900, combiner 1000 also provides significantly superior impedance matching than the classic Doherty shown in chart 1901, or its discretized analog shown in chart 1902.

Chart 1905 shows real and imaginary parts of input impedance for a configuration similar to that of chart 1903, however combiner 900 is designed to have secondary efficiency peak at −8 dB backoff rather than −6 dB. Amplifiers PA1 571, PA2 572 have output impedances of 8Ω and 5.29Ω respectively, and combiner 900 is configured to drive a 50Ω load. The real part Re(Z1) 1952 of combiner input impedance varies from about 8.3Ω at maximum power to about 20.5Ω at and below the secondary efficiency peak. Imaginary part Im (Z1) 1953 is small, with magnitude up to about 0.4Ω. An ideal combiner would have real input impedance of about 20.1 Ω with the peaking amplifier in a high-impedance state, and the observed performance deviates from this value by only about 2%. As for charts 1903, 1904, the configuration of chart 1905 maintains input impedance closer to ideal values of 8Ω and 20.1 Ω, as compared to the classic Doherty shown in chart 1901, or its discretized analog shown in chart 1902.

### 2. Insertion Loss Variation Over Operating Frequency Range

FIG. 20 is a chart series 2001-2005 depicting insertion loss across an operating frequency range for several combining networks. As a matter of convention, all charts 2001-2005 have a reversed vertical axis, so as to have better values (with lower insertion loss) appear higher on the chart.

In each chart 2001-2005, two graphs (e.g. 2014, 2015) are shown. A solid line (2014) shows the “in-system loss”, defined as power delivered to a load (Pdelivered) divided by power available from the amplifier (Pavailable). The available power Pavailable is the power that would be delivered by the amplifier into a perfectly matched load. However, because of impedance mismatch at a combiner input (e.g. nodes 511, 512 of FIG. 5, ports 911, 912 of FIG. 9, or similar nodes or ports in FIG. 4, 6-8, or 15), some power at the combiner can be reflected, so that the power entering the combiner input (Pinput) is less than Pavailable. Accordingly, a “combiner loss”, defined as Pdelivered/Pinput is also shown as a dashed line (2015) in the charts. Both insertion losses shown are for the main signal paths. As expected, less loss is better.

The combiner loss includes dissipation within combiner components (e.g. due to parasitic resistance of reactive elements) and reflection due to impedance mismatch at a combiner output (e.g. ports 413, 513, 913). The in-system loss includes both of these, as well as reflection due to impedance mismatch at the combiner input.

Often, impedance mismatch at the combiner output is a small effect, while impedance mismatch at the combiner input can be significant. The reason for this is that amplifier output impedances are usually smaller than a load impedance, so a given deviation from ideal impedance (say, by 1.0Ω) can be a small mismatch relative to a 50Ω load, with a reflection of −40 dB and forward attenuation (loss) of only 0.00004 dB. The same 1.0Ω impedance mismatch can be a large mismatch relative to an 8Ω source, with a reflection of −24 dB and forward attenuation (loss) of 0.017 dB or 0.4%.

On chart 2001, graphs 2014, 2015 show in-system and combiner losses, respectively, over a representative 16% frequency band for a classic Doherty amplifier according to FIG. 4, at maximum output power. Both amplifiers PA1 471, PA2 472 have output impedances of 8 $2, and the combiner is configured to drive a 50 $2 load. At mid-band, impedances are matched and the combiner dissipation is about 0.4 dB. The combiner loss shows small variation (about 0.01 dB) across the frequency band, but input impedance mismatch causes in-system loss to increase to about 0.6 dB at the band edges.

On chart 2002, graphs 2024, 2025 show in-system and combiner losses, respectively, over a representative 16% frequency band for a Doherty amplifier at maximum output power, with discrete combiner 600 replacing combiner 474 of FIG. 4. Both amplifiers PA1 471, PA2 472 have output impedances of 8Ω, and the combiner is configured to drive a 50Ω load. At mid-band, impedances are matched and the combiner dissipation is about 0.4 dB. The combiner loss shows variation up to about 0.05 dB across the frequency band, but input impedance mismatch causes in-system loss to increase to about 0.75 dB at the band edges. That is, the insertion loss is greater, and has greater variation, than for the classic Doherty shown in chart 2001.

On chart 2003, graphs 2034, 2035 show in-system and combiner losses, respectively, over a representative 16% frequency band for a Doherty amplifier at maximum output power, with innovative combiner 900 as combiner 574 of FIG. 5. Both amplifiers PA1 571, PA2 572 have output impedances of 8Ω, and the combiner is configured to drive a 50Ω load. At mid-band, impedances are matched and the combiner dissipation is about 0.24 dB. The combiner loss shows small variation (about 0.01 dB) across the frequency band, and input impedance mismatch causes in-system loss to increase to about 0.28 dB at the band edges. The insertion loss is significantly less, and has less variation, than for the classic Doherty shown in chart 2001, or its discretized analog shown in chart 2002.

Chart 2004 shows in-system and combiner losses for a configuration similar to that of chart 2003, however using innovative combiner 1000 rather than 900. At mid-band, impedances are matched and the combiner dissipation is about 0.24 dB. The combiner loss shows small variation (about 0.03 dB) across the frequency band, and input impedance mismatch causes in-system loss to increase to about 0.30 dB at the lower band edge. Combiner 1000 performs nearly as well as combiner 900, providing significantly superior loss performance than the classic Doherty shown in chart 2001, or its discretized analog shown in chart 2002.

Chart 2005 shows in-system and combiner losses for a configuration similar to that of chart 2003, however combiner 900 is designed to have secondary efficiency peak at −8 dB backoff rather than −6 dB. Amplifiers PA1 571, PA2 572 have output impedances of 8 Ω and 5.29Ω respectively, and combiner 900 is used to drive a 50Ω load. At mid-band, impedances are matched and the combiner dissipation is about 0.27 dB. The combiner loss shows small variation (about 0.01 dB) across the frequency band, and input impedance mismatch causes in-system loss to increase to about 0.32 dB at the band edges. The insertion loss is significantly less, and has less variation, than for the classic Doherty shown in chart 2001, or its discretized analog shown in chart 2002.

### 3. Input and Output Impedance Variation Over Operating Frequency Range

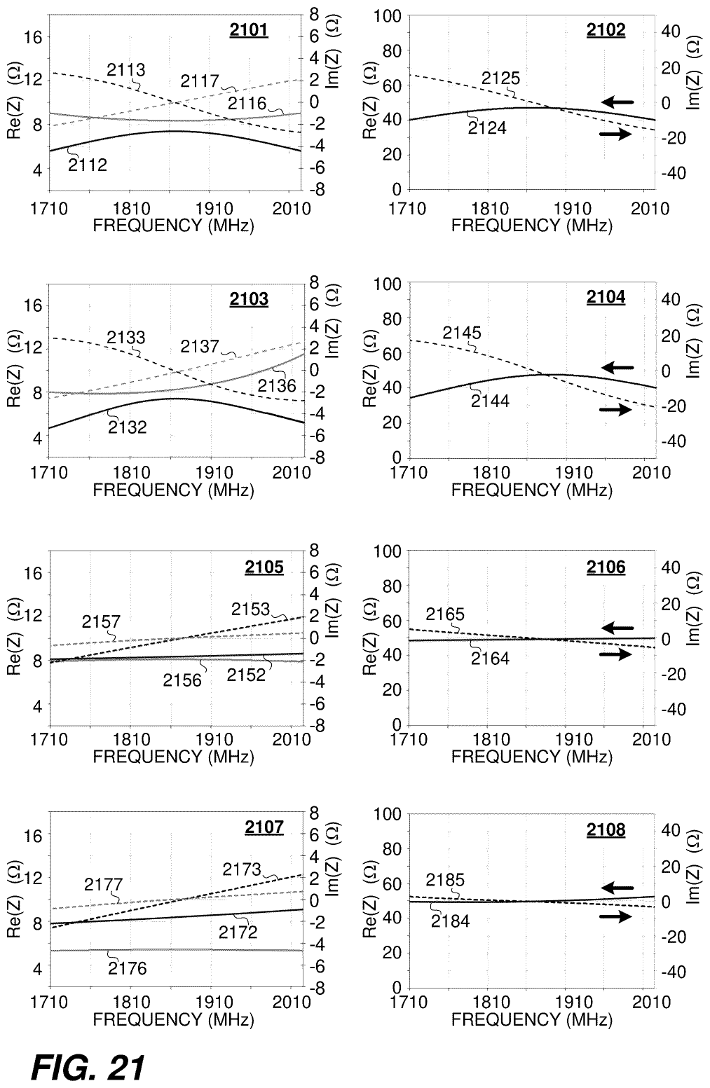

FIG. 21 is a chart series 2101-2108 depicting input and output impedances across an operating frequency range for several combining networks.

Charts 2101, 2102 show input and output impedances, respectively, over a representative 16% frequency band for a classic Doherty amplifier according to FIG. 4, at maximum output power. Both amplifiers PA1 471, PA2 472 have output impedances of 8Ω, and the combiner is configured to drive a 50Ω load. Graphs 2112, 2113 show real and imaginary parts of combiner input impedance at node 411. Graphs 2116, 2117 show real and imaginary parts of combiner input impedance at node 412. Graph 2112 shows Re(Z1) varying by about 2 Ω and graph 2113 shows Im (Z1) varying between about ±2.5Ω. Graph 2124 shows real part of output impedance Re(Z3) at port 413 drooping from nearly 48Ω at mid-band to about 40Ω at the band edges. Graph 2125 shows the imaginary part Im (Z3) varying between about ±18 Ω.

Charts 2103, 2104 show input and output impedances, respectively, over a representative 16% frequency band for a Doherty amplifier at maximum output power, with discrete combiner 600 replacing combiner 474 of FIG. 4. Both amplifiers PA1 471, PA2 472 have output impedances of 8Ω, and the combiner is configured to drive a 50Ω load. Graphs 2132, 2133 show real and imaginary parts of combiner input impedance at node 411. Graphs 2136, 2137 show real and imaginary parts of combiner input impedance at node 412. Graph 2132 shows Re(Z1) varying by about 3 Ω and graph 2113 shows Im (Z1) varying between about ±2.8Ω. Graph 2144 shows real part of output impedance Re(Z3) at port 413 drooping from nearly 48Ω at mid-band to about 35Ω at the lower band edge 1710 MHz. Graph 2145 shows the imaginary part Im (Z3) varying between about ±18 Ω. Both input and output impedance variation is greater than for the classic Doherty shown in charts 2101, 2102.

Charts 2105, 2106 show input and output impedances, respectively, over a representative 16% frequency band for a Doherty amplifier at maximum output power, with as combiner 574 of FIG. 5 implemented as innovative combiner 900. Both amplifiers PA1 571, PA2 572 have output impedances of 8Ω, and the combiner is configured to drive a 50Ω load. This Doherty amplifier has a secondary peak in efficiency at a backoff of −6 dB. Graphs 2152, 2153 show real and imaginary parts of combiner input impedance at node 511. Graphs 2156, 2157 show real and imaginary parts of combiner input impedance at node 512. Graph 2152 shows Re(Z1) varying by about 0.7 Ω and graph 2153 shows Im (Z1) varying between about ±2.1 Ω. Graph 2164 shows real part of output impedance Re(Z3) at port 513 varying by about 2Ω across the entire frequency band. Graph 2125 shows the imaginary part Im (Z3) varying between about ±6Ω. Both input and output impedance variations are significantly better than classic Doherty shown in charts 2101, 2102, or its discretized analog shown in charts 2101, 2102.

Charts 2107, 2108 show performance for an innovative Doherty amplifier designed for secondary peak in efficiency at −8 dB backoff, but otherwise similar to the configuration for charts 2105, 2106. Amplifiers PA1 571, PA2 572 have output impedances of 8Ω and 5.29Ω respectively, and combiner 900 is used to drive a 50Ω load. Graphs 2172, 2173 show real and imaginary parts of combiner input impedance at node 511. Graphs 2176, 2177 show real and imaginary parts of combiner input impedance at node 512. Graph 2172 shows Re(Z1) varying by about 1.4Ω and graph 2153 shows Im (Z1) varying between about ±2.3 Ω. Graph 2164 shows real part of output impedance Re(Z3) at port 513 varying by about 3Ω across the entire frequency band. Graph 2125 shows the imaginary part Im (Z3) varying between about ±3 Ω. Both input and output impedance variations are significantly better than classic Doherty shown in charts 2101, 2102, or its discretized analog shown in charts 2101, 2102. Performance is nearly as good as in charts 2105, 2106, and the impedance variations are still significantly better than those of charts 2101-2104.

### 4. Input Impedance, Output Impedance, and Gain Variation of Differential Doherty Amplifiers Over Operating Frequency Range

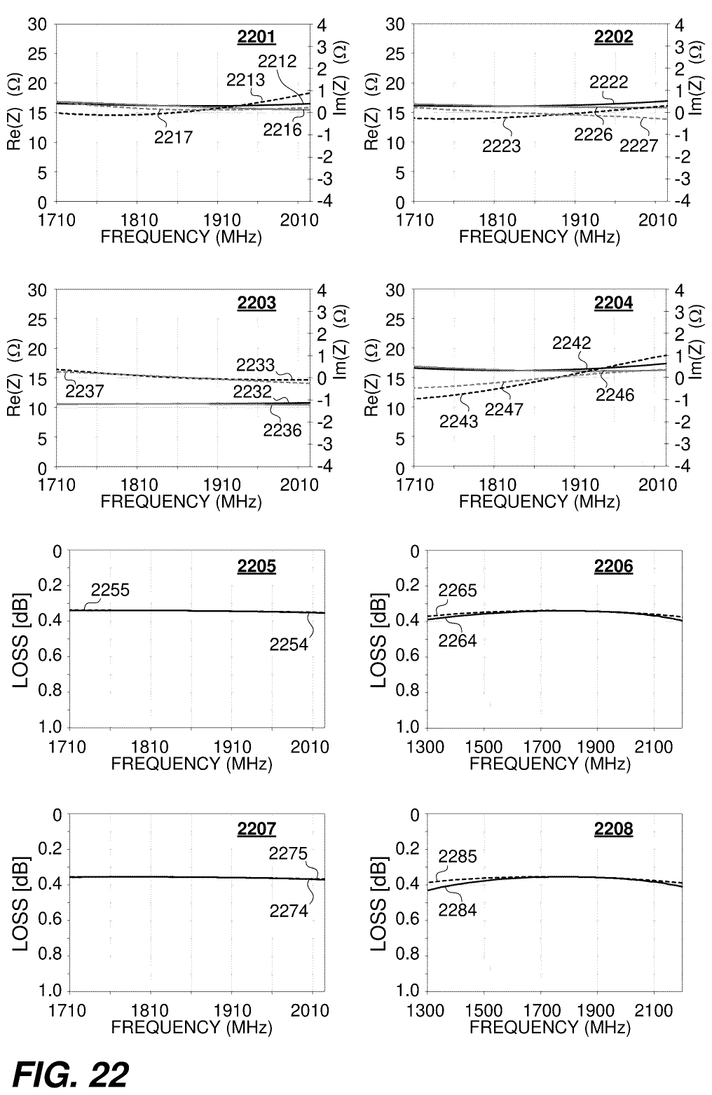

FIG. 22 is a chart series 2201-2208 depicting input impedance, output impedance, and gain across an operating frequency range for several differential combining networks. Real parts of input impedance Re(Z) are shown in solid lines, referenced to a vertical axis on the left-hand side of each chart, while imaginary parts of input impedance Im (Z) are shown in dashed lines, referenced to a vertical axis on the right-hand side.

Charts 2201, 2202 show input impedances at nodes 1565-1568 of FIG. 15, across a representative 16% frequency band. Each amplifier 1571-1574 has an output impedance of 16Ω at maximum power, and the combiners are designed to drive a 50Ω load on output port 1513. In this configuration, the differential Doherty amplifier 1500 has a secondary efficiency peak at backoff −6 dB. On chart 2201, graphs 2212, 2213 show the real and imaginary parts of input impedance Z1 at node 1565, while graphs 2216, 2217 show the real and imaginary parts of input impedance Z2 at node 1566. Re(Z1), Re(Z2) vary from about 15.5Ω to about 17Ω across the frequency range. On chart 2202, graphs 2222, 2223 show the real and imaginary parts of input impedance Z3 at node 1567, while graphs 2226, 2227 show the real and imaginary parts of input impedance Z4 at node 1568. Re(Z3), Re(Z4) vary from about 16Ω to 17 Ω. Both charts 2201, 2202 show real input impedances maintained close to the ideal value of 16 Ω, and imaginary parts of the input impedances with magnitude held below 1 Ω.

Charts 2203, 2204 also show input impedances at nodes 1565-1568 of FIG. 15, across a representative 16% frequency band. However, these charts represent a design having secondary efficiency peak at −8 dB backoff. Thus, peaking amplifiers 1571, 1572 have output impedance of 10.58Ω at maximum output power, while main amplifiers have output impedance of 16Ω. The combiners are designed to drive a 50Ω load on output port 1513. On chart 2203, graphs 2232, 2233 show the real and imaginary parts of input impedance Z1 at node 1565, while graphs 2236, 2237 show the real and imaginary parts of input impedance Z2 at node 1566. Re(Z1), Re(Z2) vary from about 10.5Ω to about 11 Ω across the frequency range. On chart 2204, graphs 2242, 2243 show the real and imaginary parts of input impedance Z3 at node 1567, while graphs 2246, 2247 show the real and imaginary parts of input impedance Z4 at node 1568. Re(Z3), Re(Z4) vary from about 16Ω to 17.5Ω. Both charts 2203, 2204 show real input impedances maintained close to their ideal values of 10.58Ω and 16 Ω, and imaginary parts of the input impedances with magnitude held below about 0.3Ω for Z1, Z2 and below about 1Ω for Z3, Z4.

Charts 2205, 2206 show insertion loss from main amplifier node 1567 to output port 1513 for the same configuration as charts 2201, 2202. On chart 2205, solid line graph 2254 shows in-system loss and is barely discernible from dashed line graph 2255 showing combiner loss. The in-system loss 2254 varies from about 0.34 dB to about 0.36 dB over the 16% operating frequency range and the combiner loss 2255 is slightly less. Despite having two 2:1 combiner stages in series, this differential Doherty combiner has losses over the entire frequency range which are less than the best insertion losses of combiners 474 or 600 at their mid-band frequencies (where impedances are matched).

As a matter of interest, chart 2206 shows insertion loss for the same configuration as chart 2205, over an extended frequency range 1300 MHz to 2200 MHz. The width of this frequency range, 900 MHz is 51% of the center frequency 1750 MHz. Even over this very wide frequency range, the worst in-system insertion loss, about 0.4 dB, is comparable to the best insertion loss of combiners 474 or 600 at their mid-band frequencies.

Charts 2207, 2208 show insertion loss from main amplifier node 1567 to output port 1513 for the same configuration as charts 2203, 2204. On chart 2207, solid line graph 2274 shows in-system loss and is barely discernible from dashed line graph 2275 showing combiner loss. The in-system loss 2274 varies from about 0.35 dB to about 0.36 dB over the 16% operating frequency range and the combiner loss 2275 is slightly less. Despite having two 2:1 combiner stages in series, this differential Doherty combiner also has less loss over the entire frequency range than the best insertion losses of combiners 474 or 600 at their mid-band frequencies (where impedances are matched). Then, chart 2208 shows insertion loss for the same configuration as chart 2205, over the extended frequency range 1300 MHz to 2200 MHz. Even over this very wide (51%) frequency range, the worst in-system insertion loss, about 0.43 dB, is comparable to the best insertion loss of combiners 474 or 600 at their mid-band frequencies.

### Additional Examples

The following are additional examples of the disclosed technologies.

Example 1 is a coupler having first, second, and third ports, including: a first T-network comprising: a first intermediate node; and first, second, and third reactive elements respectively coupling the first intermediate node to the first port, a first grounding node, and the third port; and a second T-network comprising: a second intermediate node; and fourth, fifth, and sixth reactive elements respectively coupling the second intermediate node to the second port, a second grounding node, and the third port; (a) wherein, concurrently: (i) the second T-network has an insertion phase between the second and third ports having magnitude less than or equal to 10°; and (ii) a magnitude of output impedance at the third port is greater than a magnitude of input impedance at each of the first and second ports; and (b) wherein: the first, third, and fourth reactive elements are inductors and the second, fifth, and sixth reactive elements are capacitors; or the first, third, and fourth reactive elements are capacitors and the second, fifth, and sixth reactive elements are inductors.

Example 2 includes the subject matter of Example 1, and further specifies that the first through sixth reactive elements are lossless.

Example 3 includes the subject matter of any of Examples 1-2, and further specifies that the insertion phase of the second T-network is a second insertion phase, and (c) wherein, concurrently with clauses (i) and (ii), the first T-network has an insertion phase between the first and third ports having a magnitude between 80° and 100°. That is, the insertion phase can lie in a range −100° to −80° (e.g. about −90°) or +80° to +100° (e.g. about)+90°.

Example 4 includes the subject matter of any of Examples 1-3, and further specifies that clauses (i) and (ii) are satisfied over a targeted operating frequency range.

Example 5 includes the subject matter of any of Examples 1-4, and further specifies that the first, third, and fourth reactive elements are inductors and the second, fifth, and sixth reactive elements are capacitors.

Example 6 includes the subject matter of any of Examples 1-4, and further specifies that the first, third, and fourth reactive elements are capacitors and the second, fifth, and sixth reactive elements are inductors.

Example 7 includes the subject matter of any of Examples 1-6, and further specifies that the first T-network has a first insertion loss between the first and third ports, a targeted operating frequency range is at least 15% wide and has a center frequency greater than 1 GHz; and further wherein: the first insertion loss is less than 0.45 dB over the targeted operating frequency range; or the first insertion loss varies by less than 0.14 dB over the targeted operating frequency range.

Example 8 includes the subject matter of any of Examples 1-7, and further specifies that a targeted operating frequency range is at least 15% wide and has a center frequency greater than 1 GHz; and further wherein: an output impedance of the coupler at the third port has a real part varying by less than 10% over the targeted operating frequency range; or an input impedance of the coupler at the first port has a real part varying by less than 15% over the targeted operating frequency range.

Example 9 is a system, including: the coupler of any one of Examples 1-8; a first amplifier with a first output coupled to the first port; and a second amplifier with a second output coupled to the second port; wherein the input impedances at the first and second ports match output impedances of the first and second amplifiers respectively.

Example 10 is a system, including: the coupler of any one of Examples 1-8; a main amplifier with a first output coupled to the first port; a peaking amplifier with a second output coupled to the second port; and a load coupled to the third port.

Example 11 includes the subject matter of Example 10, and further specifies that the main and peaking amplifiers variably contribute first and second amounts of output power respectively to the load and the system is configured to operate in first and second modes, wherein: in the first mode, a ratio of the first amount to the second amount is in a range 1:2 to 2:1; and in the second mode, the ratio of the first amount to the second amount exceeds 4:1.

Example 12 includes the subject matter of Example 11, and further specifies that: in the first mode, the input impedances at the first and second ports are matched to output impedances of the main amplifier and the peaking amplifier respectively; and in the second mode, the input impedance at the first port is in a range 1.5 to 2.5 times the output impedance of the main amplifier.

Example 13 includes the subject matter of any of Examples 10-12, and further specifies that the main and peaking amplifiers combine to provide output power to the load and an efficiency of the system has first and second peaks as a function of the output power: the first peak occurring at a first value of the output power, at which the input impedances at the first and second ports are matched to output impedances of the main amplifier and peaking amplifier respectively; and the second peak occurring at a backoff value of the output power, between 2 dB and 12 dB below the first value.

Example 14 is a mobile phone, including the system of any one of Examples 10-13.

Example 15 is a system, including: the coupler of any one of Examples 1-8; a main differential amplifier with a main output coupled to the second port; a peaking differential amplifier with a peaking output coupled to the first port; and a load coupled to the third port.

Example 16 includes the subject matter of Example 11, and further specifies that the insertion phase of the second T-network is a second insertion phase, and wherein, concurrently with clauses (i) and (ii), the first T-network has an insertion phase between the first and third ports having a magnitude between 80° and 100°.

Example 17 includes the subject matter of any of Examples 15-16, and further specifies that the main and peaking differential amplifiers variably contribute first and second amounts of output power respectively to the load, and the system is configured to operate in first and second modes, wherein: in the first mode, a ratio of the first amount to the second amount is in a range 1:2 to 2:1; and in the second mode, the ratio of the first amount to the second amount exceeds 4:1.

Example 18 includes the subject matter of Example 17, and further specifies that: in the first mode, the input impedances at the first and second ports are matched to output impedances of the peaking differential amplifier and the main differential amplifier respectively; and in the second mode, the input impedance at the second port is in a range 1.5 to 2.5 times the output impedance of the main differential amplifier.

Example 19 includes the subject matter of any of Examples 15-18, and further specifies that: the main differential amplifier comprises a first pair of power amplifiers having first power outputs coupled to respective inputs of a first reactive three-port differential combiner whose output port is the main output of the main differential amplifier; and the peaking differential amplifier comprises a second pair of power amplifiers having second power outputs coupled to respective inputs of a second reactive three-port differential combiner whose output port is the peaking output of the peaking differential amplifier.

Example 20 includes the subject matter of Example 19, and further specifies that the coupler and the first and second reactive three-port differential combiners form a four-way combining network configured to (i) combine output power from four amplifiers of the first pair of power amplifiers and the second pair of power amplifiers, (ii) deliver the combined output power to the load, (iii) provide respective input impedances matched to output impedances of the four amplifiers.

Example 21 includes the subject matter of any of Examples 19-20, and further includes drivers coupled to inputs of the first and second pairs of power amplifiers, wherein the drivers are configured to: drive the first pair of power amplifiers differentially; drive the second pair of power amplifiers differentially; and drive the first pair of amplifiers in quadrature with the second pair of amplifiers.

Example 22 includes the subject matter of any of Examples 19-21, and further specifies that at least one of the first and second reactive three-port differential combiners is a SILC having first, second, and third SILC ports, the SILC further comprising: a first inductor coupled between the first SILC port and a first grounding node; a second inductor coupled between the second SILC port and a second grounding node, wherein the first inductor and the second inductor have a predetermined mutual magnetic coupling factor; a third inductor coupled between the first SILC port and the third SILC port; a first capacitor coupled between the first SILC port and a third grounding node; and a second capacitor coupled between the second SILC port and the third SILC port.

Example 23 is a mobile phone, including the system of any one of Examples 15-22.

Example 24 is a method, including: receiving a first signal outputted from a first RF amplifier at a first port; receiving a second signal outputted from a second RF amplifier at a second port; conveying the received first and second signals through respective first and fourth reactive elements to first and second intermediate nodes respectively; distributing the first signal from the first intermediate node via second and third reactive elements to a first grounding node and a third port respectively; distributing the second signal from the second intermediate node via fifth and sixth reactive elements to a second grounding node and the third port respectively; and outputting a combined signal, received at the third port via the third and sixth reactive elements, to a load; (a) wherein, concurrently: (i) an insertion phase between the second and third ports has magnitude less than 10° over a targeted operating frequency range; and (ii) a magnitude of output impedance at the third port is greater than a magnitude of input impedance at each of the first and second ports; and (b) wherein: the first, third, and fourth reactive elements are inductors and the second, fifth, and sixth reactive elements are capacitors; or the first, third, and fourth reactive elements are capacitors and the second, fifth, and sixth reactive elements are inductors.

Example 25 is a method of operating a system comprising first and second amplifiers, including: varying operation of the amplifiers between a first mode and a second mode; in the first mode, performing the method of Example 24, and further specifies that: the first port presents a first matched impedance to the first amplifier, which is a source of the first signal; the second port presents a second matched impedance to the second amplifier, which is a source of the second signal; and a ratio of first power received in the first signal to second power received in the second signal is between 1:3 and 3:1; and in the second mode, receiving first and second amounts of power from the first and second amplifiers at the first and second ports respectively, wherein: an output impedance of the second amplifier has a magnitude at least twice an input impedance of the second port; and a ratio of the first amount of power to the second amount of power is at least 4:1.

Example 26 is a Doherty amplifier, including: a first power amplifier having a first output port; a second power amplifier having a second output port; a first T-network having a first input port coupled to the first output port, the first T-network comprising: a first intermediate node; and first, second, and third reactive elements respectively coupling the first intermediate node to the first input port, a first grounding node, and a third output port; and wherein the first T-network has an insertion phase, between the first input port and the third output port, having a magnitude between 80° and 100° over a targeted operating frequency range centered above 1 GHz with width at least 15%; a second T-network having a second input port coupled to the second output port, the second T-network comprising: a second intermediate node; and fourth, fifth, and sixth reactive elements respectively coupling the second intermediate node to the second input port, a second grounding node, and the third output port; wherein the second T-network has a second insertion phase between the second input port and the third output port having magnitude less than 10° over the targeted operating frequency range; (a) wherein: input impedances of the first and second input ports have first and second impedance values respectively; an output impedance of the third output port has a third impedance value; and a magnitude of the third impedance value exceeds magnitudes of each of the first and second impedance values over the targeted operating frequency range; (b) wherein: the first and second power amplifiers combine to deliver variable output power through the third output port to a load; at a first value of the output power, the input impedance of the first input port is matched to the output impedance of the first output port; and at a second value of the output power, between 2 dB and 10 dB below the first value, the Doherty amplifier has a peak efficiency; and (c) wherein: the first, third, and fourth reactive elements are inductors and the second, fifth, and sixth reactive elements are capacitors; or the first, third, and fourth reactive elements are capacitors and the second, fifth, and sixth reactive elements are inductors.

### General Considerations

As used in this application, the singular forms “a,” “an,” and “the” include the plural forms unless the context clearly dictates otherwise. Additionally, the terms “includes” and “incorporates” mean “comprises.” Further, the term “coupled” encompasses mechanical, electrical, magnetic, optical, as well as other practical ways of coupling or linking items together, and does not exclude the presence of intermediate elements between the coupled items. Furthermore, as used herein, the terms “or” and “and/or” mean any one item or combination of items in the phrase, and do not imply that the joined terms are mutually exclusive.

The systems, methods, and apparatus described herein should not be construed as limiting in any way. Instead, this disclosure is directed toward all novel and non-obvious features and aspects of the various disclosed embodiments, alone and in various combinations and subcombinations with one another. The disclosed systems, methods, and apparatus are not limited to any specific aspect or feature or combinations thereof, nor do the disclosed things and methods require that any one or more specific advantages be present or problems be solved.

Although the operations of some of the disclosed methods are described in a particular, sequential order for convenient presentation, it should be understood that this manner of description encompasses rearrangement, unless a particular ordering is required by specific language set forth below. For example, operations described sequentially can in some cases be rearranged or performed concurrently. Moreover, for the sake of simplicity, the attached figures may not show the various ways in which the disclosed things and methods can be used in conjunction with other things and methods. Additionally, the description sometimes uses terms like “amplify,” “couple,” “distribute,” “form,” “generate,” “output,” “provide,” “receive,” “transmit,” and “use,” as high-level descriptions of the actual operations that are performed. The actual operations that correspond to these terms will vary depending on the particular implementation and are readily discernible by one of ordinary skill in the art.

Theories of operation, scientific principles, or other theoretical descriptions presented herein in reference to the apparatus or methods of this disclosure have been provided for the purposes of better understanding and are not intended to be limiting in scope. The apparatus and methods in the appended claims are not limited to those apparatus and methods that function in the manner described by such theories of operation.

Some examples can be implemented with the aid of electronic design automation (EDA) tools. Certain details of suitable hardware, such as electrical, electronic, or RF circuitry, are well known and need not be set forth in detail in this disclosure.

The disclosed methods, apparatus, and systems should not be construed as limiting in any way. Instead, the present disclosure is directed toward all novel and nonobvious features and aspects of the various disclosed embodiments, alone and in various combinations and subcombinations with one another. The disclosed methods, apparatus, and systems are not limited to any specific aspect or feature or combination thereof, nor do the disclosed embodiments require that any one or more specific advantages be present or problems be solved. The technologies from any example can be combined with the technologies described in any one or more of the other examples.

In view of the many possible embodiments to which the principles of the disclosed subject matter may be applied, it should be recognized that the illustrated embodiments are only preferred examples of the disclosed subject matter and should not be taken as limiting the scope of the claims. Rather, the scope of the claimed subject matter is defined by the following claims. We therefore claim all that comes within the scope of these claims and their equivalents.

I claim:

1. A coupler having first, second, and third ports, and comprising:
a first T-network comprising:
a first intermediate node; and
first, second, and third reactive elements respectively coupling the first intermediate node to the first port, a first grounding node, and the third port; and
a second T-network comprising:
a second intermediate node; and
fourth, fifth, and sixth reactive elements respectively coupling the second intermediate node to the second port, a second grounding node, and the third port;
wherein, concurrently:
(i) the second T-network has an insertion phase between the second and third ports having magnitude less than or equal to 10°; and
(ii) a magnitude of output impedance at the third port is greater than a magnitude of input impedance at each of the first and second ports; and
wherein:
the first, third, and fourth reactive elements are inductors and the second, fifth, and sixth reactive elements are capacitors; or
the first, third, and fourth reactive elements are capacitors and the second, fifth, and sixth reactive elements are inductors.

2. The coupler of claim 1, wherein the first through sixth reactive elements are lossless.

3. The coupler of claim 1, wherein the insertion phase of the second T-network is a second insertion phase, and wherein, concurrently with clauses (i) and (ii), the first T-network has an insertion phase between the first and third ports having a magnitude between 80° and 100°.

4. The coupler of claim 1, wherein clauses (i) and (ii) are satisfied over a targeted operating frequency range.

5. A system comprising:
the coupler of claim 1;
a first amplifier with a first output coupled to the first port; and
a second amplifier with a second output coupled to the second port;
wherein the input impedances at the first and second ports match output impedances of the first and second amplifiers respectively.

6. A system comprising:
the coupler of claim 1;
a main amplifier with a first output coupled to the first port;
a peaking amplifier with a second output coupled to the second port; and
a load coupled to the third port.

7. The system of claim 6, wherein the main and peaking amplifiers variably contribute first and second amounts of output power respectively to the load and the system is configured to operate in first and second modes, wherein:
in the first mode, a ratio of the first amount to the second amount is in a range 1:2 to 2:1; and
in the second mode, the ratio of the first amount to the second amount exceeds 4:1.

8. The system of claim 6, wherein the main and peaking amplifiers combine to provide output power to the load and an efficiency of the system has first and second peaks as a function of the output power:
the first peak occurring at a first value of the output power, at which the input impedances at the first and second ports are matched to output impedances of the main amplifier and peaking amplifier respectively; and
the second peak occurring at a backoff value of the output power, between 2 dB and 12 dB below the first value.

9. A mobile phone comprising the system of claim 6.

10. A system comprising:
the coupler of claim 1;
a main differential amplifier with a main output coupled to the second port;
a peaking differential amplifier with a peaking output coupled to the first port; and
a load coupled to the third port.

11. The system of claim 10, wherein the insertion phase of the second T-network is a second insertion phase, and wherein, concurrently with clauses (i) and (ii), the first T-network has an insertion phase between the first and third ports having a magnitude between 80° and 100°.

12. The system of claim 10, wherein the main and peaking differential amplifiers variably contribute first and second amounts of output power respectively to the load, and the system is configured to operate in first and second modes, wherein:
in the first mode, a ratio of the first amount to the second amount is in a range 1:2 to 2:1; and
in the second mode, the ratio of the first amount to the second amount exceeds 4:1.

13. The system of claim 10, wherein:
the main differential amplifier comprises a first pair of power amplifiers having first power outputs coupled to respective inputs of a first reactive three-port differential combiner whose output port is the main output of the main differential amplifier; and
the peaking differential amplifier comprises a second pair of power amplifiers having second power outputs coupled to respective inputs of a second reactive three-port differential combiner whose output port is the peaking output of the peaking differential amplifier.

14. The system of claim 13, wherein at least one of the first and second reactive three-port differential combiners is a SILC having first, second, and third SILC ports, the SILC further comprising:
a first inductor coupled between the first SILC port and a first grounding node;
a second inductor coupled between the second SILC port and a second grounding node, wherein the first inductor and the second inductor have a predetermined mutual magnetic coupling factor;
a third inductor coupled between the first SILC port and the third SILC port;
a first capacitor coupled between the first SILC port and a third grounding node; and
a second capacitor coupled between the second SILC port and the third SILC port.

15. A mobile phone comprising the system of claim 10.

16. The coupler of claim 1, wherein the first T-network has a first insertion loss between the first and third ports, a targeted operating frequency range is at least 15% wide and has a center frequency greater than 1 GHz; and further wherein:
the first insertion loss is less than 0.45 dB over the targeted operating frequency range; or
the first insertion loss varies by less than 0.14 dB over the targeted operating frequency range.

17. The coupler of claim 1, wherein a targeted operating frequency range is at least 15% wide and has a center frequency greater than 1 GHz; and further wherein:
an output impedance of the coupler at the third port has a real part varying by less than 10% over the targeted operating frequency range; or
an input impedance of the coupler at the first port has a real part varying by less than 15% over the targeted operating frequency range.

18. A method comprising:
receiving a first signal outputted from a first RF amplifier at a first port;
receiving a second signal outputted from a second RF amplifier at a second port;
conveying the received first and second signals through respective first and fourth reactive elements to first and second intermediate nodes respectively;
distributing the first signal from the first intermediate node via second and third reactive elements to a first grounding node and a third port respectively;
distributing the second signal from the second intermediate node via fifth and sixth reactive elements to a second grounding node and the third port respectively; and
outputting a combined signal, received at the third port via the third and sixth reactive elements, to a load;
wherein, concurrently:
(i) an insertion phase between the second and third ports has magnitude less than 10° over a targeted operating frequency range; and
(ii) a magnitude of output impedance at the third port is greater than a magnitude of input impedance at each of the first and second ports; and
wherein:
the first, third, and fourth reactive elements are inductors and the second, fifth, and sixth reactive elements are capacitors; or
the first, third, and fourth reactive elements are capacitors and the second, fifth, and sixth reactive elements are inductors.

19. A method of operating a system comprising first and second amplifiers, the method comprising:
varying operation of the amplifiers between a first mode and a second mode;
in the first mode, performing the method of claim 18, wherein:
the first port presents a first matched impedance to the first amplifier, which is a source of the first signal;
the second port presents a second matched impedance to the second amplifier, which is a source of the second signal; and
a ratio of first power received in the first signal to second power received in the second signal is between 1:3 and 3:1; and
in the second mode, receiving first and second amounts of power from the first and second amplifiers at the first and second ports respectively, wherein:
an output impedance of the second amplifier has a magnitude at least twice an input impedance of the second port; and
a ratio of the first amount of power to the second amount of power is at least 4:1.

20. A Doherty amplifier comprising:
a first power amplifier having a first output port;
a second power amplifier having a second output port;
a first T-network having a first input port coupled to the first output port, the first T-network comprising:
a first intermediate node; and
first, second, and third reactive elements respectively coupling the first intermediate node to the first input port, a first grounding node, and a third output port; and
wherein the first T-network has an insertion phase, between the first input port and the third output port, having a magnitude between 80° and 100° over a targeted operating frequency range centered above 1 GHz with width at least 15%;
a second T-network having a second input port coupled to the second output port, the second T-network comprising:
a second intermediate node; and
fourth, fifth, and sixth reactive elements respectively coupling the second intermediate node to the second input port, a second grounding node, and the third output port;
wherein the second T-network has a second insertion phase, between the second input port and the third output port, having magnitude less than 10° over the targeted operating frequency range;
wherein:
input impedances of the first and second input ports have first and second impedance values respectively;
an output impedance of the third output port has a third impedance value; and
a magnitude of the third impedance value exceeds magnitudes of each of the first and second impedance values over the targeted operating frequency range;
wherein:
the first and second power amplifiers combine to deliver variable output power through the third output port to a load;
at a first value of the output power, the input impedance of the first input port is matched to the output impedance of the first output port; and
at a second value of the output power, between 2 dB and 10 dB below the first value, the Doherty amplifier has a peak efficiency; and
wherein:
the first, third, and fourth reactive elements are inductors and the second, fifth, and sixth reactive elements are capacitors; or
the first, third, and fourth reactive elements are capacitors and the second, fifth, and sixth reactive elements are inductors.
